(19) United States
(12) Patent Application Publication
(10) Pub. No.: US 2026/0214940 A1
(43) Pub. Date: Jul. 23, 2026

(54) SEMICONDUCTOR STRUCTURES AND METHODS OF FORMING SAME

(71) Applicant: Taiwan Semiconductor Manufacturing Company, Ltd., Hsin-Chu (TW)

(72) Inventors: Jung-Hao Chang, Taichung City (TW); I-Hung Li, New Taipei City (TW); Hsien-Chung Huang, Hsinchu (TW); Bing-Hung Chen, San-Xia Town (TW); Pinyen Lin, Rochester, NY (US)

(21) Appl. No.: 19/029,394

(22) Filed: Jan. 17, 2025

(51) Int. Cl. H10D 30/67; H01L 21/3065; H01L 21/308; H01L 21/311; H10D 30/00; H10D 30/01; H10D 30/43; H10D 62/10; H10D 62/13; H10D 84/01

(52) U.S. Cl. CPC H10D 30/6735; H10D 30/014; H10D 30/0191; H10D 30/43; H10D 30/502; H10D 62/118; H10D 62/151; H10D 84/013; H10D 84/0151; H10P 50/242; H10P 50/283; H10P 50/695

(57) ABSTRACT

A method includes forming a metal gate structure wrapping around a stack of channel layers, forming a trench cutting the metal gate structure into two isolated segments, and forming a gate isolation structure in the trench. Forming the trench includes performing a plasma etching process to the metal gate structure, the plasma etching process includes a first step and a second step after the first step. The first step has a first source power and a first bias power, the second step has a second source power and a second bias power. A ratio of the first source power to the second source power is about 1:1 to about 5:1, and the first bias power is less than the second bias power.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, as stacked device structures are introduced to enable further density reduction for advanced IC technology nodes, frontside interconnect structures and backside interconnect structures may be needed to facilitate electrical connection to and/or operation of devices of the stacked device structures, such as an upper transistor and a lower transistor thereof. For example, gate cut features are formed to separate nearby metal gate structures. Although existing interconnect structures and gate cut features have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1 and 2 illustrate flowcharts of a method for forming a semiconductor structure, according to one or more aspects of the present disclosure.

FIGS. 3, 7, 17, 18, 21, 25, 29, and 31 illustrate fragmentary top views of an exemplary semiconductor structure during various fabrication stages in the method of FIGS. 1 and 2, according to one or more aspects of the present disclosure.

FIGS. 4, 5, 8A, 8B, 9, 10, 11, 12, 13, 16, 19A, 19B, 20, 22A, 22B, 23, 24, 26A, 26B, 27, and 28 illustrate fragmentary cross-sectional views of the exemplary semiconductor structure during various fabrication stages in the method of FIGS. 1 and 2, according to one or more aspects of the present disclosure.

FIGS. 6 and 30 illustrate fragmentary perspective views of the exemplary semiconductor structure during various fabrication stages in the method of FIGS. 1 and 2, according to one or more aspects of the present disclosure.

FIGS. 14A and 15A illustrate diagrams of a source power and a bias power during various fabrication stages in the method of FIGS. 1 and 2, according to one or more aspects of the present disclosure.

FIGS. 14B and 15B illustrate fragmentary schematic cross-sectional diagrams of the exemplary semiconductor structure during various fabrication stages in the method of FIGS. 1 and 2, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Stacked transistor structures can provide further density reduction for advanced integrated circuit (IC) technology nodes (particularly as they advance to 3 nm (N3) and below), especially when the stacked transistor structures include multigate devices, such as fin-like field effect transistors (FinFETs), gate-all-around (GAA) transistors including nanowires and/or nanosheets, other types of multigate devices, etc. Stacked transistor structures include vertically stack transistors. For example, a stacked transistor structure can include a first transistor (i.e., an upper/top transistor) disposed over a second transistor (i.e., a lower/bottom transistor). The transistor stack can provide a CFET when the first transistor and the second transistor are of opposite conductivity type (i.e., an n-type transistor and a p-type transistor).

In semiconductor fabrication, cut metal gate (CMG) process refers to a process for forming a dielectric feature to divide a continuous gate structure into two or more segments. Such a dielectric feature may be referred to as a gate cut feature, a cut feature, or a gate isolation structure. In some example processes, the gate cut feature is formed using photolithography and etch processes from a front side (or frontside) of a substrate (such as a wafer). As the scaling down of semiconductor device continues, for example, in a CFET, it becomes increasingly difficult to form the gate cut feature.

The present disclosure relates generally to methods of forming gate cut features and device-level interconnects for stacked device structures, such as a transistor stack having an n-type field effect transistor (NFET) and a p-type field effect transistor (PFET) (i.e., a complementary field effect transistor (CFET)).

In an example process, a structure (e.g., a CFET) is provided. The structure includes a first stack of channel layers disposed over a substrate and a second stack of channel layers disposed over the first stack of channel layers. The first and the second stacks of channel layers are separated by a middle dielectric layer. The structure includes a gate structure wrapping around the first and the second stacks of channel layers. A trench is formed to cut the gate structure into two isolated segments. Forming the trench includes performing a plurality of etching cycles. At least one cycle of the plurality of etching cycles includes a first step, a second step, and a third step. The source power has a step change (increase or decrease) from the first step to the second step. The bias power has a step increase from the first step to the second step. The source power and the bias power are both zero in the third step. A gate cut feature and an L-shaped conductive feature surrounded by the gate cut feature are then formed in the trench. By performing the plurality of etching cycles, variation of depths of the trench may be reduced to about 10 nm to about 30 nm. Accordingly, depths of the gate cut feature and depths of the L-shaped conductive feature may also have reduced variations. Thus, control of a backside process (e.g., a chemical mechanical polishing (CMP) process) may be improved. In addition, tapered angle of sidewalls of the gate cut feature may be reduced to less than about 7 degrees, which may increase resistance of the L-shaped conductive feature.

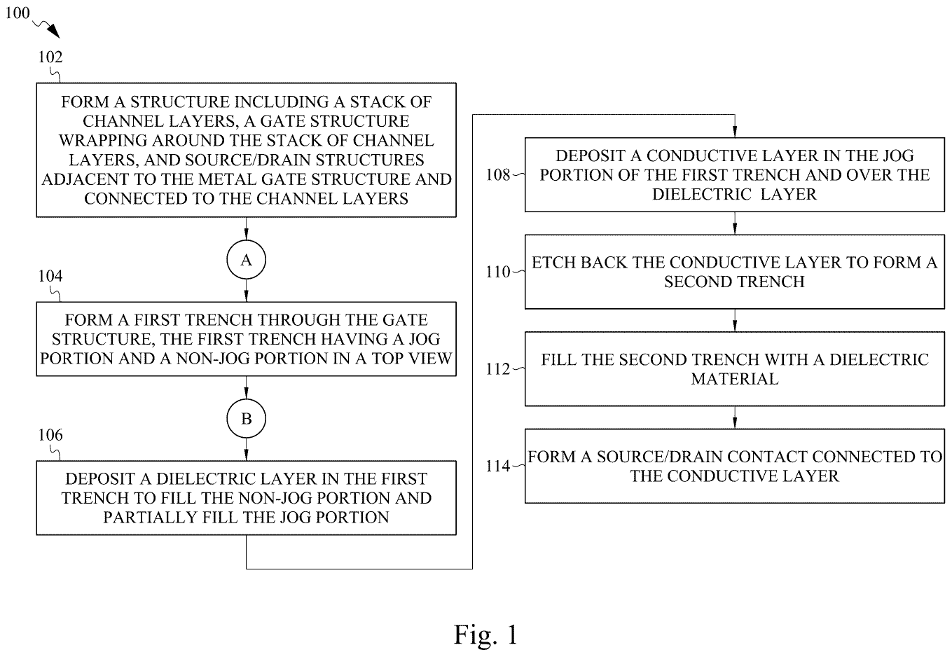

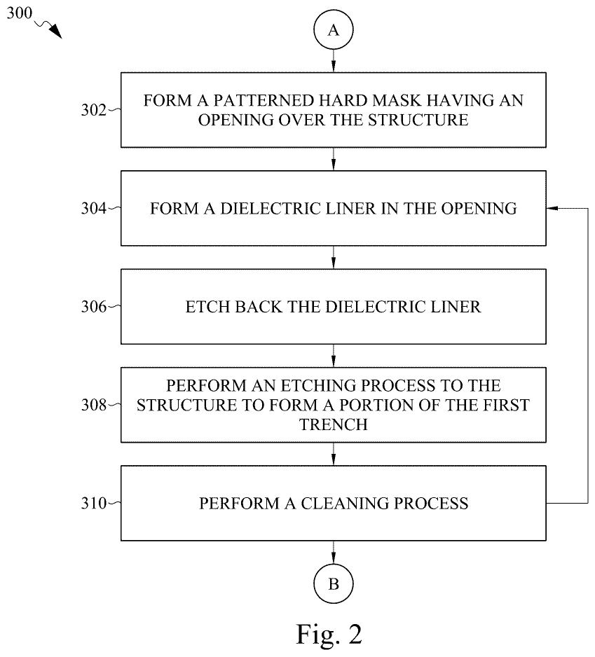

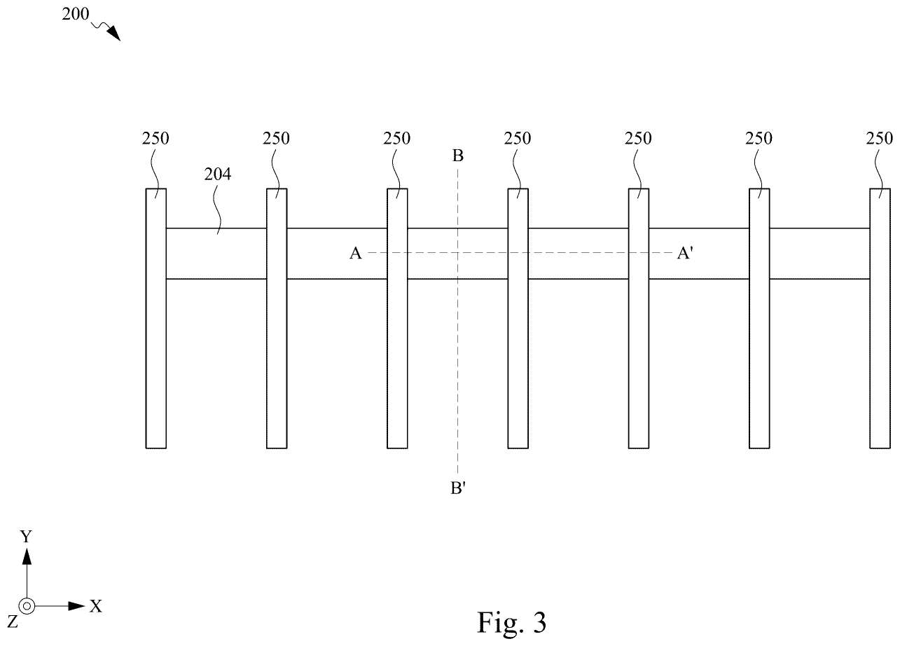

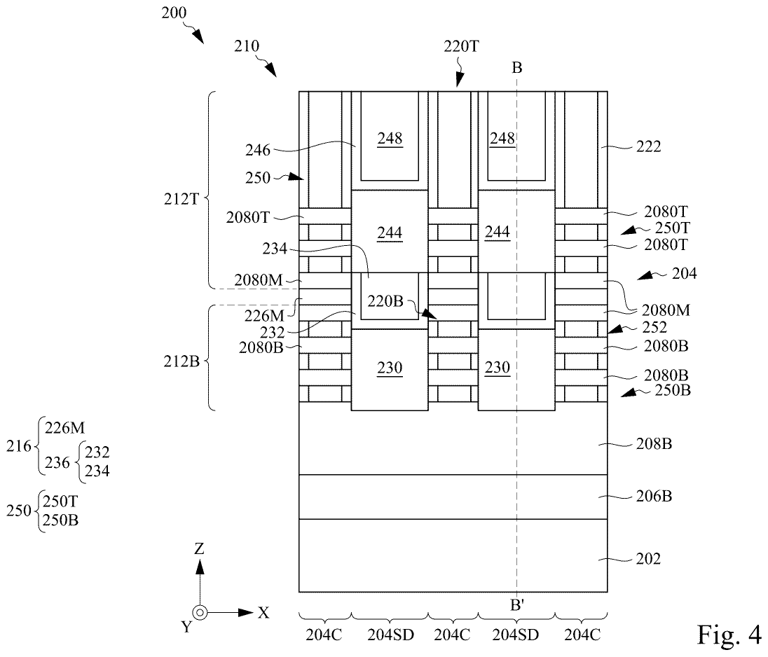

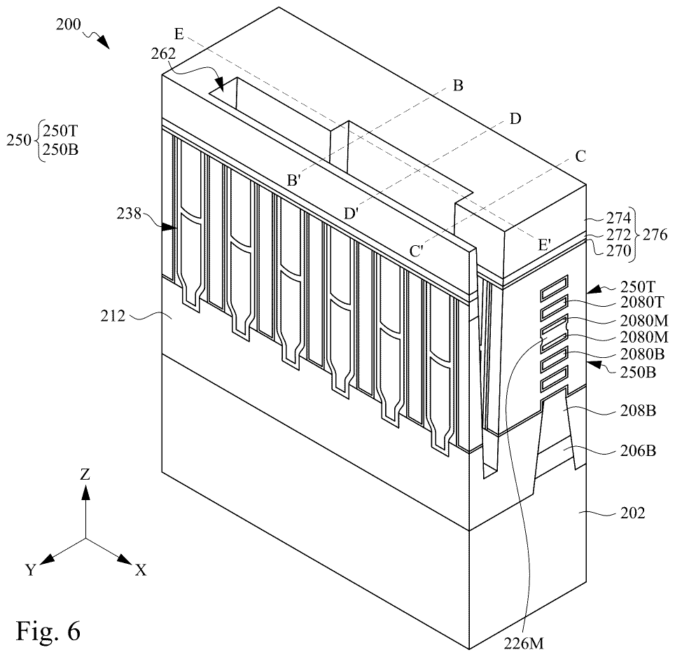

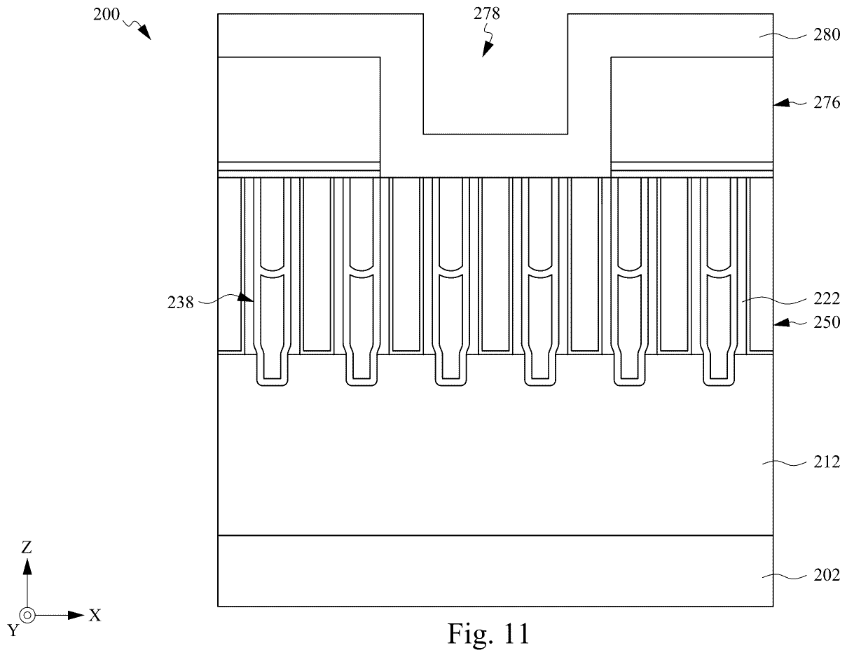

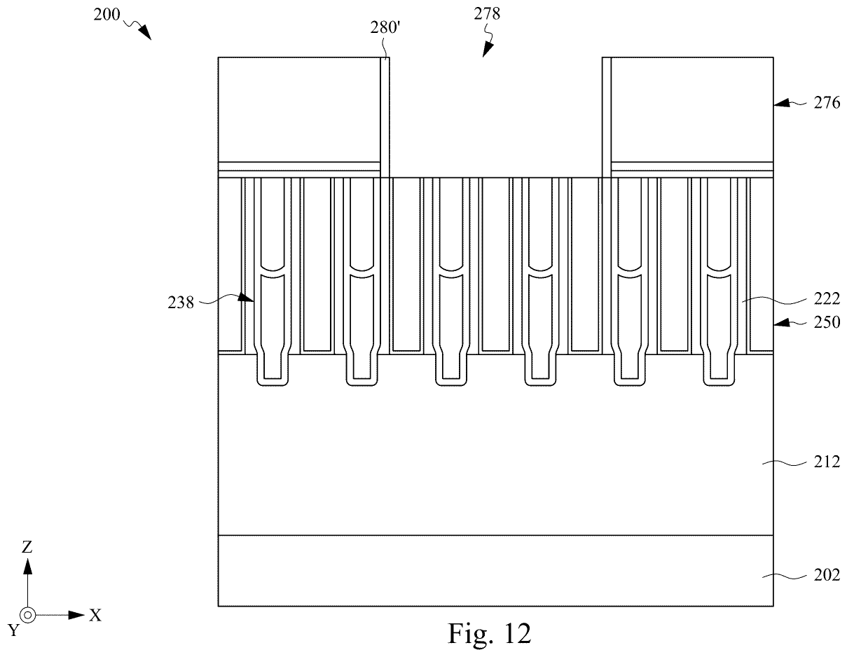

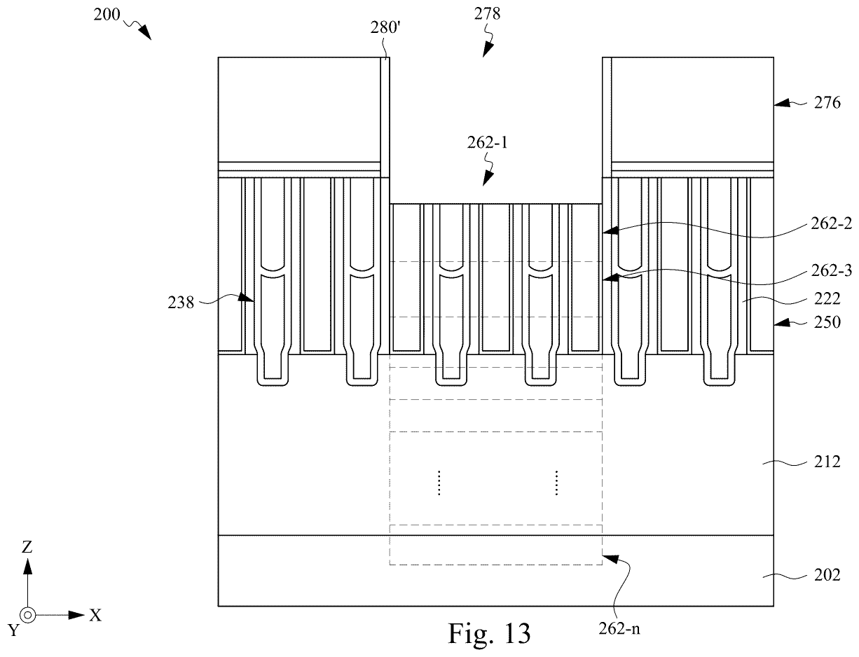

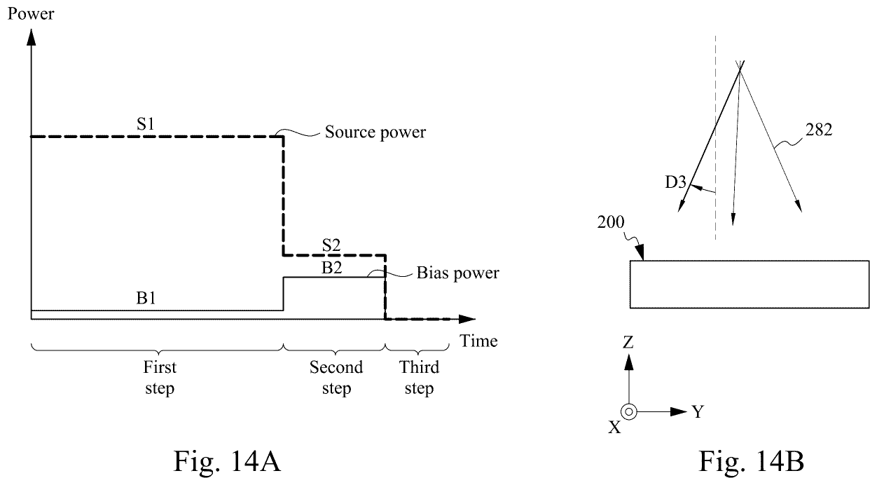

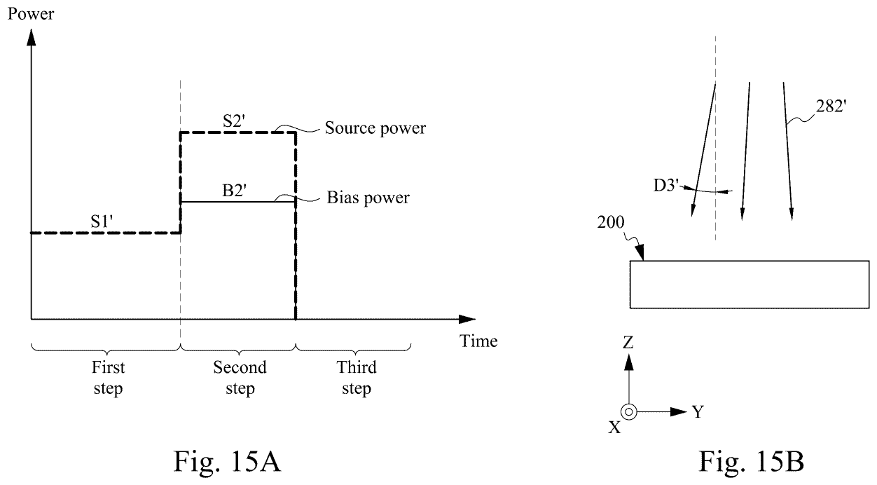

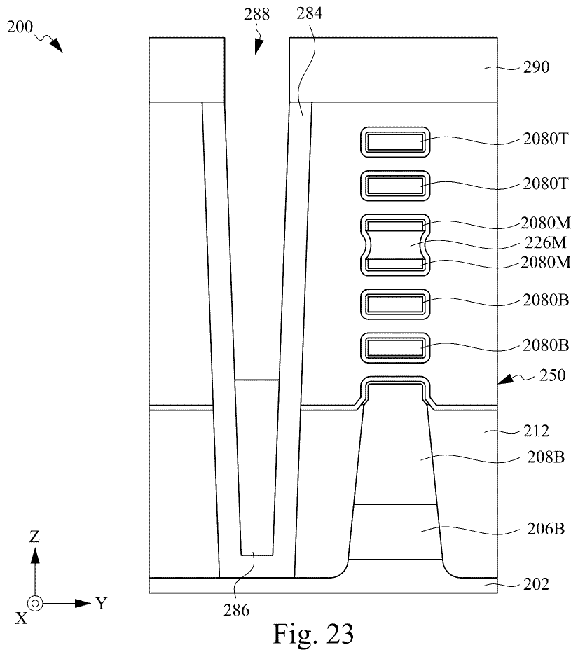

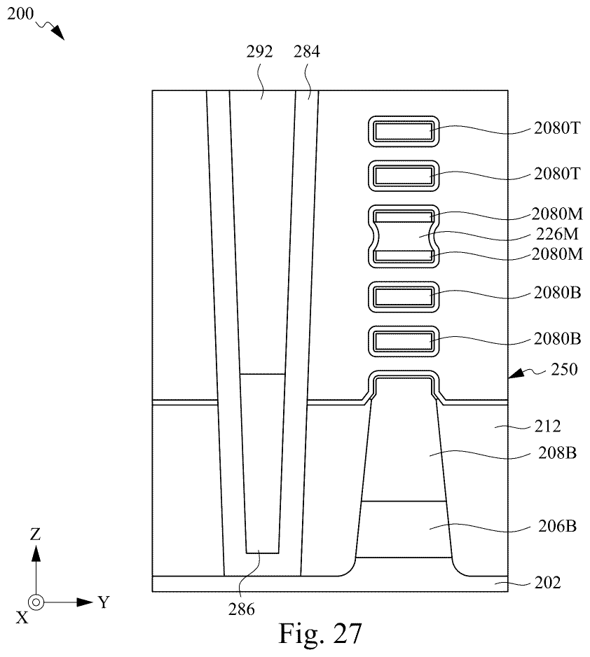

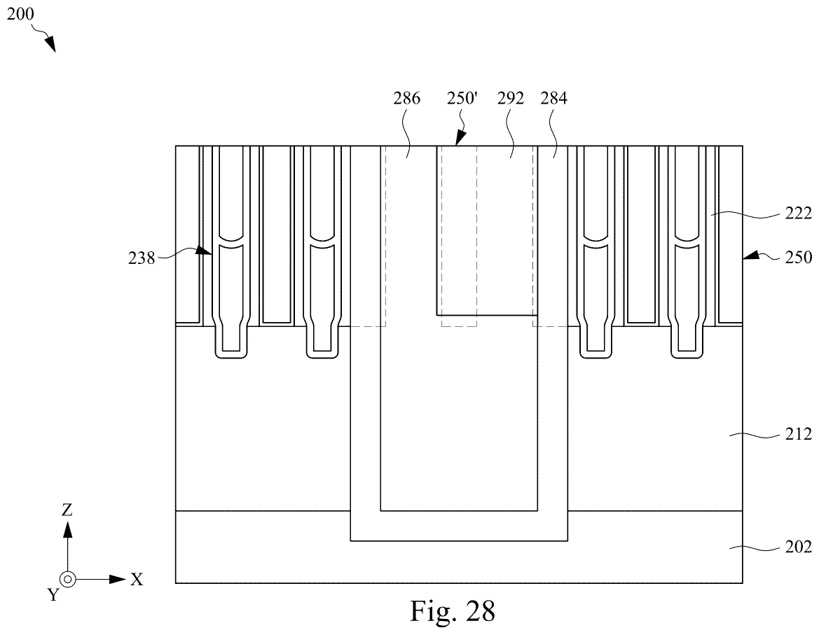

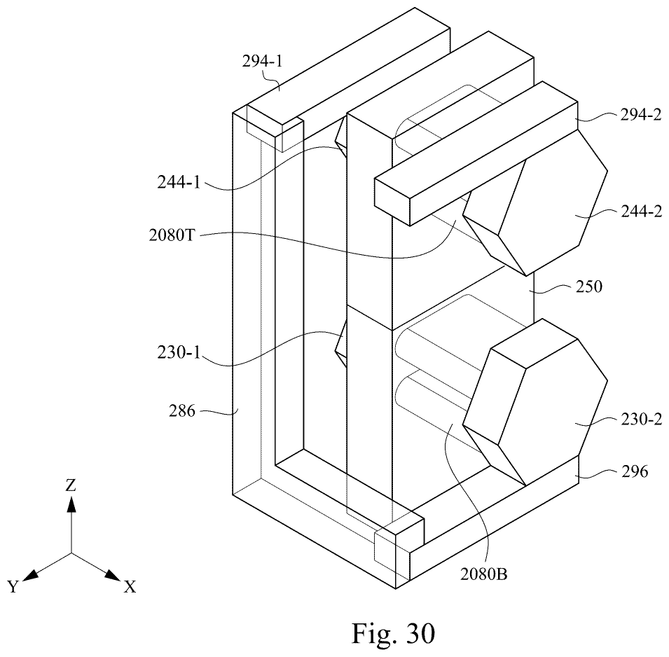

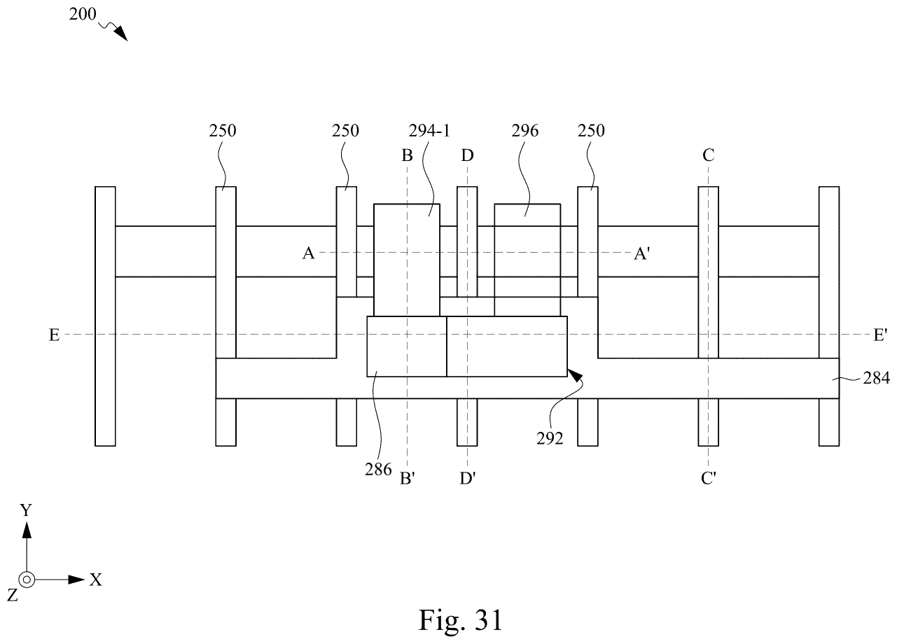

The various aspects of the present disclosure will now be described in more detail with reference to the figures. In that regard, FIG. 1 is a flowchart illustrating method 100 of forming a semiconductor structure according to embodiments of the present disclosure. FIG. 2 is a flowchart illustrating block 104 of method 100 in FIG. 1. Method 100 is described below in conjunction with FIGS. 3-31. FIGS. 3, 7, 17, 18, 21, 25, 29, and 31 are fragmentary top views of a structure 200 at different stages of fabrication according to embodiments of method 100 in FIG. 1. FIGS. 4-5, 8A-13, 16, 19A-20, 22A-24, and 26A-28 are fragmentary cross-sectional views of the structure 200 at different stages of fabrication according to embodiments of method 100 in FIG. 1. FIGS. 6 and 30 are fragmentary perspective views of the structure 200 at different stages of fabrication according to embodiments of method 100 in FIG. 1. FIGS. 14A and 15A illustrate diagrams of a source power and a bias power at different stages of fabrication according to embodiments of method 100 in FIG. 1. FIGS. 14B and 15B illustrate fragmentary schematic cross-sectional diagrams of the structure 200 during various fabrication stages in method 100 in FIGS. 1, according to one or more aspects of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of method 100. Not all steps are described herein in detail for reasons of simplicity. Because the structure 200 will be fabricated into a semiconductor structure or a semiconductor device, the structure 200 may be referred to herein as a semiconductor structure 200 or a semiconductor device 200 as the context requires. For avoidance of doubts, the X, Y and Z directions in FIGS. 3-13, 14B, 15B, and 16-31 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Referring to FIGS. 1 and 3-5, method 100 includes a block 102 where a structure 200 is formed or provided. FIGS. 3-5 have been simplified for the sake of clarity to better understand the inventive concepts of the present disclosure. Additional features can be added in the structure 200, and some of the features described below can be replaced, modified, or eliminated in other embodiments of the structure 200.

FIG. 3 illustrates a fragmentary top view of the structure 200. The structure 200 includes an active region 204 extending lengthwise along the X-direction and gate structures 250 extending lengthwise along the Y-direction. As will be described further below, the active region 204 includes a vertical stack of nanostructures (or channel members) stacked along the Z-direction. Each of the gate structures 250 includes a bottom segment and a top segment over the bottom segment. The top segment and the bottom segment may include different work function layer arrangement or different dipole components.

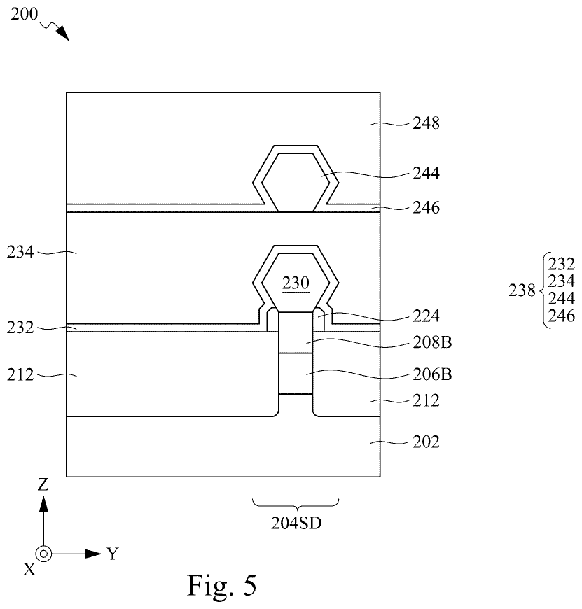

FIGS. 4 and 5 illustrate fragmentary cross-sectional views of the structure 200 taken along line A-A′ and B-B′ in FIG. 3, respectively. Referring to FIG. 4, the structure 200 includes a substrate 202 and various features (e.g., a stacked device structure 210) that have been fabricated on the substrate 202. The structure 200 includes a bottom silicon germanium layer 206B over the substrate 202 and a bottom silicon layer 208B over the bottom silicon germanium layer 206B. Along the Y-direction, the active region 204 includes channel regions 204C are interleaved by source/drain regions 204SD. The stacked device structure 210 includes a device stack, such as a top device 212T vertically stacked over a bottom device 212B, disposed over the substrate 202. In the depicted embodiment, the device 212T and the device 212B are stacked back-to-front. For example, a backside of the device 212T is attached and/or bonded to a frontside of the device 212B. An insulation structure 216 is disposed between and separates the device 212T and the device 212B. The insulation structure 216 may be a single layer/feature or a multilayer/feature structure, and in the depicted embodiment, includes an insulation structure 226M and an insulation structure 236. In the depicted embodiment, the stacked device structure 210 is fabricated monolithically, and thus can be referred to as a monolithic stacked device structure 210. In some embodiments, the stacked device structure 210 is fabricated sequentially, and thus can be referred to as a sequential stacked device structure 210.

The device 212T and the device 212B each include at least one electrically functional device, such as a top transistor 220T and a bottom transistor 220B, respectively. The stacked device structure 210 thus includes a transistor stack having a top transistor (e.g., the transistor 220T) and a bottom transistor (e.g., the transistor 220B) separated and/or electrically isolated from one another by the isolation structure 216. In some embodiments, the transistor 220B and the transistor 220T are transistors of an opposite conductivity type. For example, the transistor 220B is a p-type transistor, and the transistor 220T is an n-type transistor, or vice versa. In such embodiments, the transistor 220B and the transistor 220T form a CFET. In some embodiments, the transistor 220B and the transistor 220T are transistors of a same conductivity type. For example, the transistor 220B and the transistor 220T are both n-type transistors or both p-type transistors.

The device 212T includes various features and/or components, such as semiconductor layers 2080T, semiconductor layers 2080M, gate spacers 222, inner spacers 252, epitaxial source/drain feature 244, a contact etch stop layer (CESL) 246, an interlayer dielectric (ILD) layer 248, and a gate structure segment 250T. The device 212B also includes various features and/or components, such as a bottom silicon layer 208B, semiconductor layers 2080B, semiconductor layers 2080M, isolation features 212, inner spacers 252, epitaxial source/drain features 230, a CESL 232, an ILD layer 234, and a gate structure segment 250B. The gate structure segment 250T and the gate structure segment 250B are collectively referred to as the gate structure 250 of the stacked device structure 210, such as a metal gate or a high-k/metal gate of a CFET. In some embodiments, the insulation structure 226M includes a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). In furtherance of the depicted embodiment, the epitaxial source/drain features 244 are separated and/or electrically isolated from the epitaxial source/drain features 230 by the insulation structure 236. In some embodiments, the insulation structure 236 may be formed by a portion of the CESL 232 and the ILD layer 234.

In the depicted embodiment, the transistor 220B is a GAA transistor. For example, the transistor 220B has two channels provided by the semiconductor layers 2080B (also referred to as channel layers), which are suspended over the substrate 202 and extend between respective source/drain features (e.g., the epitaxial source/drain features 230). In some embodiments, the transistor 220B includes more or less channels (and thus more or less semiconductor layers 2080B). The transistor 220B further has the gate structure segment 250B disposed over its semiconductor layers 2080B and between its epitaxial source/drain features 230, and the inner spacers 252 are disposed between its gate structure segment 250B and its epitaxial source/drain features 230. Along a gate widthwise direction (e.g., in an X-Z plane), the gate structure segment 250B is over the top semiconductor layer 2080B, between the semiconductor layers 2080B, and between the bottom semiconductor layer 2080B and the bottom silicon layer 208B. Along a gate lengthwise direction (e.g., in a Y-Z plane), the gate structure segment 250B wraps around the semiconductor layers 2080B. During operation of the GAA transistor, current can flow through the semiconductor layers 2080B and between the epitaxial source/drain features 230. The semiconductor layers 2080M are suspended over substrate 202 and extend between respective insulation structures 236, and the insulation structures 226M are disposed between the semiconductor layers 2080M of the device 212B and the semiconductor layers 2080M of the device 212T.

In the depicted embodiment, the transistor 220T is also a GAA transistor. For example, the transistor 220T has two channels provided by the semiconductor layers 2080T (also referred to as channel layers), which are suspended over the substrate 202 and extend between respective source/drain features (e.g., the epitaxial source/drain features 244). In some embodiments, the transistor 220T includes more or less channels (and thus more or less semiconductor layers 2080T). The transistor 220T further has the gate structure segment 250T disposed over its semiconductor layers 2080T and between its epitaxial source/drain features 244, the gate structure segment 250T disposed between respective gate spacers 222, and the inner spacers 252 disposed between its gate structure segment 250T and its epitaxial source/drain features 244. Along a gate widthwise direction, the gate structure segment 250T is over the top semiconductor layer 2080T, between the semiconductor layers 2080T, and between the bottom semiconductor layer 2080T and the semiconductor layer 2080M. Along a gate lengthwise direction, the gate structure segment 250T wraps around the semiconductor layers 2080T. During operation of the GAA transistor, current can flow through the semiconductor layers 2080T and between the epitaxial source/drain features 244.

The substrate 202, the bottom silicon layer 208B, the semiconductor layers 2080T, the semiconductor layers 2080M, and the semiconductor layers 2080B include an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In the depicted embodiment, the substrate 202, the bottom silicon layer 208B, the semiconductor layers 2080T, the semiconductor layers 2080M, and the semiconductor layers 2080B include silicon. In some embodiments, the semiconductor layers 2080T and the semiconductor layers 2080B include different semiconductor materials, such as silicon and silicon germanium, respectively, or vice versa. In some embodiments, the substrate 202 is a semiconductor-on-insulator substrate, such as a silicon-on-insulator substrate, a silicon germanium-on-insulator substrate, or a germanium-on-insulator substrate. The substrate 202 and the bottom silicon layer 208B may include various doped regions, such as p-wells and n-wells. The n-wells are doped with n-type dopants, such as phosphorus, arsenic, other n-type dopant, or a combination thereof. The p-wells are doped with p-type dopants, such as boron, indium, other p-type dopant, or a combination thereof.

The isolation features 212 electrically isolate active device regions and/or passive device regions. For example, the isolation features 212 separate and electrically isolate the bottom silicon layer 208B from each other and/or other device regions/features. The isolation features 212 include silicon oxide, silicon nitride, silicon oxynitride, other suitable isolation material (for example, including silicon, oxygen, nitrogen, carbon, etc.), or a combination thereof. The isolation features 212 may have a multilayer structure. For example, the isolation features 212 include a bulk dielectric (e.g., an oxide layer) over a dielectric liner (for example, silicon nitride, silicon oxide, silicon oxynitride, silicon oxycarbonitride, or a combination thereof). In another example, the isolation features 212 include a bulk dielectric over a doped liner, such as a boron silicate glass (BSG) liner and/or a phosphosilicate glass (PSG) liner. Dimensions and/or characteristics of the isolation features 212 are configured to provide shallow trench isolation (STI) structures, deep trench isolation (DTI) structures, local oxidation of silicon (LOCOS) structures, other suitable isolation structures, or a combination thereof. In the depicted embodiment, the isolation features 212 may be STIs.

The gate spacers 222 are disposed along sidewalls of upper portions of the gate structure segment 250T, the inner spacers 252 are disposed under the gate spacers 222 along sidewalls of the gate structure segment 250T and/or gate structure segment 250B, and fin spacers 224 are disposed along sidewalls of the bottom silicon layer 208B. The inner spacers 252 are between the semiconductor layers 2080B and 2080T and between the bottom semiconductor layers 2080B and the bottom silicon layer 208B. The gate spacers 222, the inner spacers 252, and the fin spacers 224 include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). The gate spacers 222, the inner spacers 252, and the fin spacers 224 may include different materials and/or different configurations (e.g., different numbers of layers). In some embodiments, the gate spacers 222, the inner spacers 252, and the fin spacers 224, or a combination thereof have a multilayer structure. In some embodiments, the gate spacers 222 and/or the fin spacers 224 include more than one set of spacers, such as seal spacers, offset spacers, sacrificial spacers, dummy spacers, main spacers, or a combination thereof. The various sets of spacers may have different compositions.

The epitaxial source/drain features 230 and the epitaxial source/drain features 244 have the same or different compositions and/or materials depending on configurations of their respective transistors. The epitaxial source/drain features 230 and the epitaxial source/drain features 244 may be doped with n-type dopants and/or p-type dopants. In some embodiments, the epitaxial source/drain features 230 and/or the epitaxial source/drain features 244 include silicon that may be doped with carbon, phosphorous, arsenic, other n-type dopant, or a combination thereof (e.g., Si:C epitaxial source/drains, Si:P epitaxial source/drains, or Si:C:P epitaxial source/drains). In some embodiments, the epitaxial source/drain features 230 and/or the epitaxial source/drain features 244 include silicon germanium or germanium, which may be doped with boron, other p-type dopant, or a combination thereof (e.g., Si:Ge:B epitaxial source/drains). In the depicted embodiment, the epitaxial source/drain features 230 include silicon germanium doped with boron, and the epitaxial source/drain features 244 include silicon doped with phosphorous. In some embodiments, the epitaxial source/drain features 230 and/or the epitaxial source/drain features 244 include more than one epitaxial semiconductor layer, where the epitaxial semiconductor layers may include the same or different materials and/or the same or different dopant concentrations. In some embodiments, the epitaxial source/drain features 230 and/or the epitaxial source/drain features 244 include materials and/or dopants that achieve desired tensile stress and/or compressive stress in adjacent channel regions (e.g., formed by the semiconductor layers 2080T and the semiconductor layers 2080B). As used herein, source/drain region, source/drain feature, epitaxial source/drain, epitaxial source/drain feature, etc. may refer to a source of a device (e.g., the transistor 220T and/or the transistor 220B), a drain of a device (e.g., the transistor 220T and/or the transistor 220B), or a source and/or a drain of multiple devices.

The ILD layer 248 and the ILD layer 234 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or a combination thereof. In some embodiments, the ILD layer 248 and/or the ILD layer 234 includes a dielectric material having a dielectric constant that is less than a dielectric constant of silicon dioxide. The CESL 232 and the CESL 246 include a material different than a material of the ILD layer 234 and the ILD layer 248, respectively. In some embodiments, CESL 232 and the CESL 246 include silicon nitride and the ILD layer 234 and the ILD layer 248 include silicon oxide. The ILD layer 234, the ILD layer 248, the CESL 232, the CESL 246, or a combination thereof may include a multilayer structure. The ILD layer 234, the ILD layer 248, the CESL 232, and the CESL 246 may be collectively referred to as a dielectric structure 238.

Although not depicted, the gate structure 250 may include an interfacial layer interfacing the channel layers 2080T, 2080B, 2080M, and the bottom silicon layer 208B in the channel region 204C, gate dielectrics over the interfacial layer, and a gate electrode over the gate dielectrics. The gate dielectrics includes at least one dielectric gate layer. The interfacial layer may include a dielectric material, such as SiO₂, SiGeOₓ, HfSiO, SiON, other dielectric material, or a combination thereof. In some embodiments, the gate dielectrics include a high-k dielectric layer. The high-k dielectric layer includes a high-k dielectric material, which generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TIO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr) TiO₃ (BST), Si₃N₄, HfO₂—Al₂O₃, other high-k dielectric material, or a combination thereof. For example, the gate dielectrics include a hafnium-based oxide (e.g., HfO₂) layer and/or a zirconium-based oxide (e.g., ZrO₂) layer. In some embodiments, the interfacial layer and/or the high-k dielectric layer has a multilayer structure.

The gate electrode may be disposed over respective gate dielectrics. The gate electrode includes at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAIN, TaCN, TaC, TaSiN, other electrically conductive material, or a combination thereof. In some embodiments, the gate electrode includes a work function layer. The work function layer is a conductive layer tuned to have a desired work function, such as an n-type work function or a p-type work function, for an n-type transistor or a p-type transistor, respectively. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or a combination thereof. In some embodiments, the gate electrode includes a bulk layer over the gate dielectric and/or the work function layer. The bulk layer includes a suitable conductive material, such as Al, W, Cu, Ti, Ta, TiN, TaN, polysilicon, other suitable metal(s) and/or alloys thereof, or a combination thereof. In some embodiments, the gate electrode includes a barrier (blocking) layer over the work function layer and/or the gate dielectric. The barrier layer includes a material that prevents or eliminates diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride (e.g., W₂N), titanium silicon nitride (TiSiN), tantalum silicon nitride (TaSiN), other suitable metal nitride, or a combination thereof.

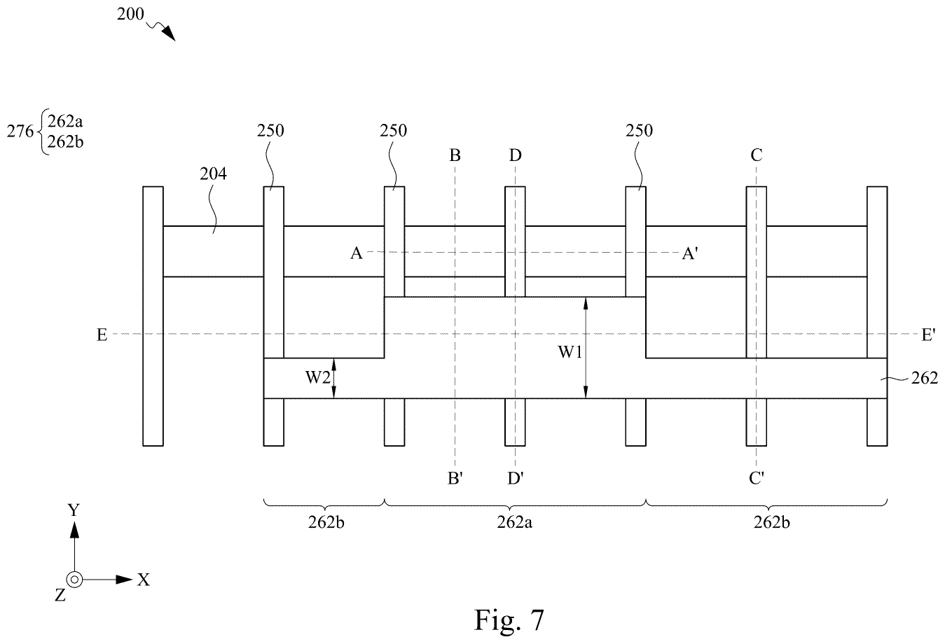

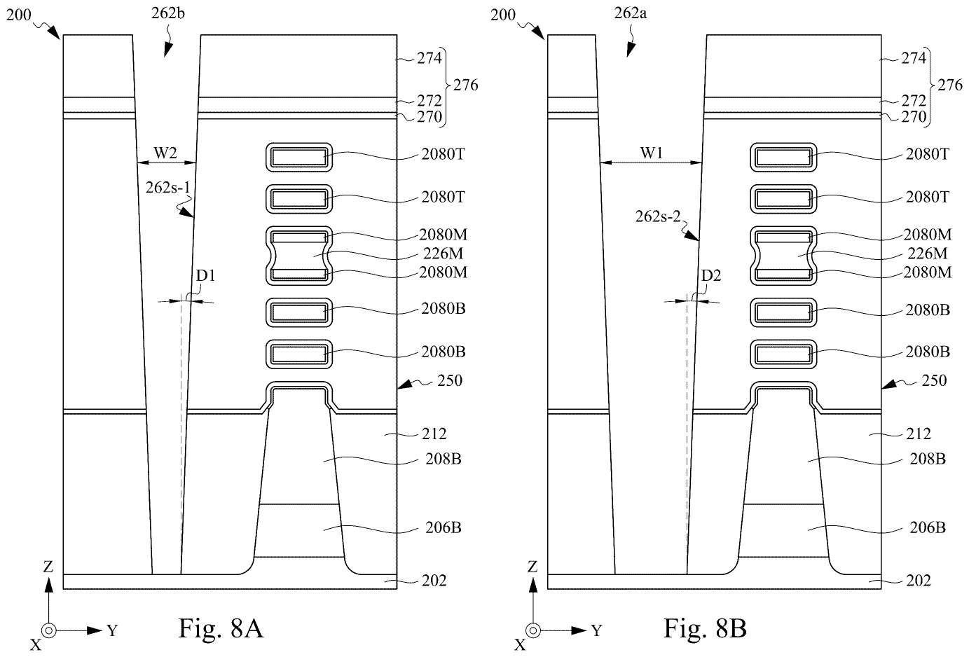

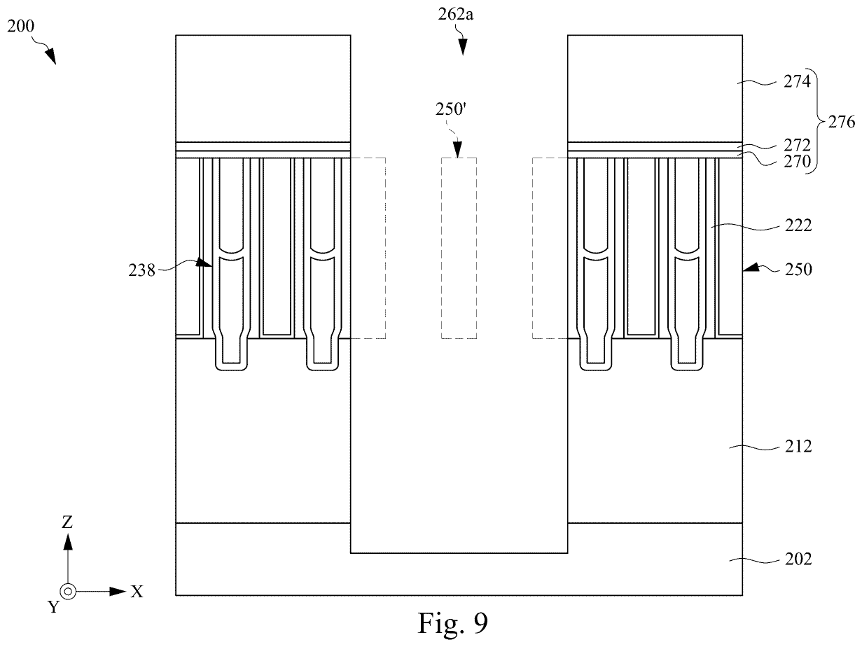

Referring to FIGS. 1 and 6-9, method 100 includes a block 104 where a first trench 262 (or a gate isolation trench 286) is formed to cut the gate structure 250 into isolated segments. FIGS. 8A, 8B, and 9 illustrate fragmentary cross-sectional views of the structure 200 taken along lines C-C′, D-D′, E-E′, respectively, as in FIGS. 6 and 7.

Referring to FIG. 6, in some embodiments, the gate structure segments 250B and 250T of a same gate structure 250 are in contact. In some other embodiments, the gate structure segments 250B and 250T of a same gate structure 250 are isolated, for example, by a dielectric layer. In such embodiments, the dielectric layer is disposed between the gate structure segments 250B and 250T of a same gate structure 250.

Referring to FIGS. 6-7, the first trench 262 extends lengthwise along the X-direction from a top view. In some embodiments, the first trench 262 includes a jog portion 262a and one or more non-jog portions 262b connected to the jog portion 262a. Numbers of the gate structures 250 divided by the jog portion 262a and the non-jog portion(s) 250b in the figures are for examples only and do not limit the scope of the disclosure. The jog portion 262a has a width W1 along the Y-direction, the non-jog portion 262b has a width W2 along the Y-direction. W1 may be an averaged width of the jog portion 262a and W2 may be an averaged width of the non-jog portion. W2 is less than W1. W1 may be about 25 nm to about 65 nm, and W2 may be about 10 nm to about 45 nm. A ratio of W2 to W1 may be about 1:4 to about 1:1.5.

Referring to FIGS. 8A-8B, the first trench 262 extends through the gate structure 250. In the depicted embodiments, the first trench 262 extends through the isolation feature 212 and stops at a top surface of the substrate 202. In some other embodiments, the first trench 262 extends into and stops in the isolation feature 212. In yet some other embodiments, the first trench 262 extends into the substrate 202. The first trench 262 may have tapered sidewalls (e.g., sidewall 262s-1, sidewall 262s-2) as depicted. The first trench 262 may have a top width and a bottom width less than the top width. In some other embodiments, the first trench 262 has vertical sidewalls. In the cross-sectional view of FIG. 8A, an angle D1 (or tapered angle D1) is between the tapered sidewall 262s-1 and a vertical direction (the dashed line). In the cross-sectional view of FIG. 8B, an angle D2 (or tapered angle D2) is between the tapered sidewall 262s-2 and a vertical direction (the dashed line). A difference between D1 and D2 may be less than about 3 degrees, alternatively less than about 2 degrees, alternatively less than about 1 degree. In some embodiments, D1 is the same as D2.

Referring to FIG. 9, the first trench 262 (e.g., the jog portion 262a) may extend into the substrate 202. In the depicted embodiments, the jog portion 262a divides the isolated segments of the gate structures 250. The isolated segments are projected in the cross-sectional view of FIG. 9 and shown as dashed rectangles 250′.

Forming the first trench 262 may use any suitable methods. In an embodiment, photolithography process(es) and etching process(es) are performed to the structure 200 to form the first trench 262. Forming the first trench 262 may include forming a patterned hard mask layer 276 over the structure 200 and performing etching processes using the hard mask layer as an etch mask. Portions of the gate structures 250, the gate spacers 222, the dielectric structure 238, and/or the isolation feature 212 are removed to form the first trench 262. The etching process(es) may include wet etch, dry etch, or a combination thereof. The etching process(es) may use one or more etchant.

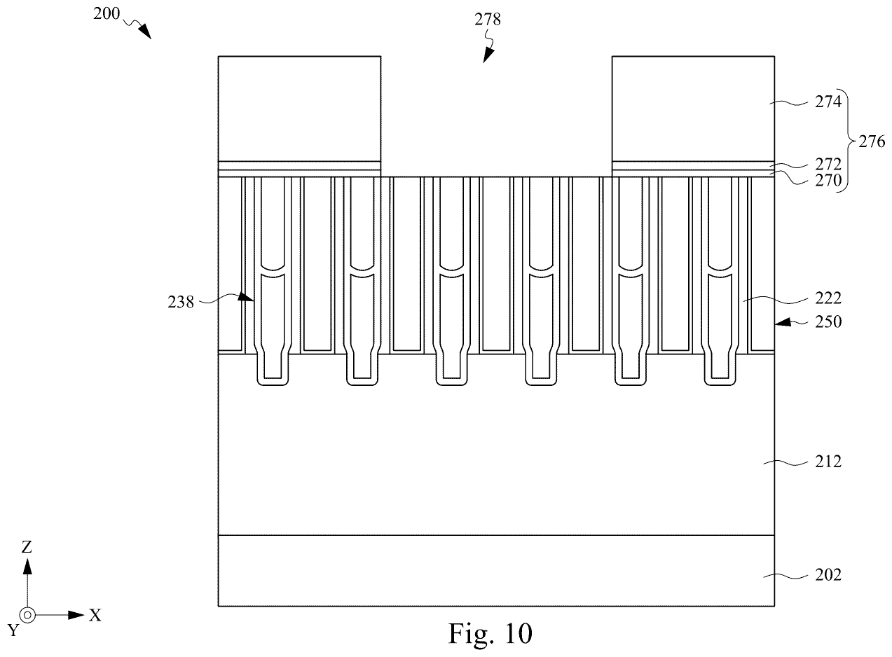

FIGS. 10-13 illustrates fragmentary cross-sectional views of the structure 200 taken along line E-E′ as in FIGS. 6 and 7 at different stages in forming the first trench 262. Referring to FIGS. 1-2 and 10, operations at block 104 of method 100 include a block 302 where the patterned hard mask layer 276 is formed. The patterned hard mask layer 276 includes an opening 278 that is substantially aligned with the to-be-formed first trench 262. In an example process, a hard mask layer and a photoresist are deposited over the workpiece 200. The hard mask layer may include multiple layers, such as a first hard mask layer 270, second hard mask layer 272, and a third mask layer 274 as depicted. In some embodiments, the first hard mask layer 270 includes silicon nitride and the second hard mask layer 272 includes silicon oxide. The third hard mask layer 274 may include silicon nitride.

The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer to form the patterned hard mask layer 276. The patterned hard mask layer 276 is then applied as an etch mask to etch the gate structure 250 and the other features therebelow. The etch process may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, oxygen, hydrogen, other suitable gases, or combinations thereof.

In some embodiments, forming the first trench 262 includes a plurality of etching cycles. In some embodiments, at least one of the plurality of etching cycles includes operations at blocks 304-310. In some embodiments, each of the plurality of etching cycles includes operations at blocks 304-310.

Referring to FIGS. 1-2 and 11, the etching cycle may include a block 304 where a dielectric liner 280 is formed along a bottom surface and sidewalls of the opening 278. The dielectric liner 280 may be a single layer or a multi-layer. In some embodiments, the dielectric liner 280 includes silicon, oxygen, nitrogen, or carbon. For example, the dielectric liner 280 includes silicon nitride, silicon carbonitride, silicon oxycarbonitride, silicon oxycarbide, or silicon oxynitride. In some embodiments, the dielectric liner 280 includes an oxide, such as silicon oxide. The dielectric liner 280 may have a thickness between about 0.5 nm and about 3 nm. The dielectric liner 280 may be formed by conformally depositing the dielectric liner 280 over the structure 200. The term “conformally” may be used herein for ease of description of a layer having substantially uniform thickness over various regions of the structure 200. The dielectric liner 280 may be deposited by atomic layer deposition (ALD), chemical vapor deposition (CVD), or any other suitable deposition process.

Referring to FIGS. 1-2 and 12, the etching cycle may include a block 306 where the dielectric liner 280 is anisotropically etched back to expose the gate structures 250, the dielectric structure 238, and the gate spacers 222. After the etching back, a remaining portion 280′ (also referred to as a remaining dielectric liner 280′) of the dielectric liner 280 remains along sidewalls of the opening 278. The remaining dielectric liner 280′ may have a thickness between about 0.1 nm to about 3 nm, alternatively between about 0.1 nm to about 2 nm. The etch back process may be a dry etch process that includes use of argon (Ar), a fluorine-containing etchant (for example, SF₆, NF₃, CH₂F₂, CHF₃, C₄F₈, C₄F₆, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, oxygen, hydrogen, other suitable gases, or combinations thereof. The remaining dielectric liner 280′ may protect features (e.g., the hard mask layer 276) covered by the remaining dielectric liner 280′ in the following processes of the etching cycle. A portion of the remaining dielectric liner 280′ may be etched during the following processes of the etching cycle.

Referring to FIGS. 1-2 and 13-15B, the etching cycle may include a block 308 where an etching process is performed to form a first portion 262-1 of the first trench 262. The etching process may include an anisotropic etch process. The etching process may include a dry etching process (e.g., a reactive-ion etching (RIE), an inductively coupled plasma etching (ICP), an ICP-RIE, a plasma etching) that uses argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, oxygen, hydrogen, other suitable gases, or combinations thereof. In some embodiments, the dry etching process includes uses of chlorine (Cl₂), oxygen (O₂), boron trifluoride (BCl₃), carbon tetrafluoride (CF₄), or a combination thereof.

The etching process may include a first step, a second step, and a third step. In some embodiments, the etching process may be performed at a source power and a bias power as illustrated in FIGS. 14A and 15A. The source power may include radio frequency (RF) or microwave power. The source power and the bias power in the etching process have level-to-level pulsing. In some embodiments, the source power has a first pulse in the first step and a second pulse in the second step. The bias power may include a first pulse in the first step and a second pulse in the second step (shown in FIG. 14A) or include one pulse in the second step (shown in FIG. 15A). The fragmentary schematic cross-sectional diagrams of the structure 200 in FIGS. 14B and 15B correspond to embodiments represented in FIGS. 14A and 15A, respectively.

Referring to FIGS. 14A-14B, the source power S1 in the first step may be in a range of about 1500 Watt (W) to about 2300 W, the source power S2 in the second step may be in a range of about 250 W to about 800 W. A ratio of S1 to S2 may be about 1:1 to about 5:1. If the ratio is too high, S2 may be too small, and the amount of the plasma in the second step may be too small. If the ratio is too small, S2 may be too large, which may impact the effect of the bias power in the second step. In some embodiments, the bias power B1 in the first step may be greater than zero W and equal to or less than about 100 W, the bias power B2 in the second step may be in a range of about 200 W to about 600 W. In some embodiments, a ratio of B1 to B2 is about 1:3 to about 1:50. The bias power B1 is less than the source power S1. A ratio of S1 to B1 may be about 20:1 to about 60:1. The bias power B2 may be less than the source power S2. A ratio of S2 to B2 may be about 1.3:1 to about 2.5:1. The source power and the bias power may be both zero in the third step. Time durations of the first step, the second step, and the third step are t1, t2, and t3, respectively. In some embodiments, t1 is greater than t2 and t2 is greater than t3. A ratio of t1 to t2 may be about 1:1 to about 4:1. A ratio of t2 to t3 may be about 1:1 to about 5:1. A sum of t1, t2, and t3 may be about 1 millisecond (ms) to about 100 seconds.

In the first step, plasma (e.g., including radicals, ions) may be generated under operating conditions such as the source power S1 and the bias power B1 in a chamber. In the second step, the generated radicals and ions may be directed (e.g., accelerated, bombard) toward the structure 200 to etch the features exposed in the opening 278 by the bias power B2. Operations of the second step may be in a same chamber as the first step.

In the embodiments represented in FIGS. 14A and 14B, the bias power is an AC power. In such embodiments, the plasma may be directed toward the structure 200 along directions 282 as the arrows in FIG. 14B. An angle D3 between the directions 282 and a vertical direction (the dashed line) may be zero degree to about 90 degrees. The level-to-level pulsing of the source power and the bias power disclosed herein improve ion angle distribution (IAD) at the second step of the generated radicals and ions. IAD refers to the statistical distribution of angles (e.g., the angle D3) at which radicals and ions strike the structure 200. Improved IAD may reduce variation of depths and/or widths of the first trench 262, reduce tapered angles (e.g., D1, D2) of the sidewalls of the first trench 262, and/or reduce variation of the tapered angles in different cross-sectional views (e.g., across the jog portion 262a in FIG. 8B and across the non-jog portion 262b in FIG. 8A). In some embodiments, the angles D1 and D2 as in FIGS. 8A and 8B may be greater than zero degree and less than about 30 degrees. In such embodiments, the difference between D1 and D2 may be less than about 2 degrees.

In some other embodiments, referring to FIGS. 15A-15B, the source power S1′ in the first step may be in a range of about 400 W to about 1000 W, the source power S2′ in the second step may be in a range of about 800 W to about 2300 W. S1′ may be less than $2′. A ratio of S1′ to S2′ may be about 1:1 to about 1:5. If the ratio is too high, S2′ may be too small, and the amount of the plasma in the second step may be too small. If the ratio is too small, S2′ may be too large, which may impact the effect of the bias power in the second step. In some embodiments, the bias power in the first step is zero W. In some embodiments, the bias power in the first step is greater than zero W and less than the bias power in the second step. The bias power in the first step may be zero W to about 50 W. The bias power B2′ in the second step may be in a range of about 200 W to about 800 W. The bias power B2′ may be less than the source power S2′. A ratio of S2′ to B2′ may be about 1.2:1 to about 2.5:1. The source power and the bias power may be both zero in the third step. Time durations of the first step, the second step, and the third step are t1′, t2′, and t3′, respectively. In some embodiments, t1′ is equal to or greater than t2′, and t2′ may be equal to or greater than t3′. A ratio of t1′ to t2′ may be about 1:1 to about 2:1. A ratio of t2′ to t3′ may be about 1:1 to about 5:1. A sum of t1′, t2′, and t3′ may be about 0.1 millisecond (ms) to about 100 seconds.

In the first step, plasma (e.g., including radicals, ions) may be generated under operating conditions such as the source power S1′ in a chamber. The generated radicals and ions may be adsorbed to surfaces (e.g., exposed surfaces in the opening 278) of the structure 200. In the second step, more plasma (e.g., including radicals, ions) may be generated under operating conditions such as the source power S2′ and the bias power B2′, and the generated radicals and ions may be directed (e.g., accelerated, bombard) toward the structure 200 to activate surface reaction(s) and/or to etch the features exposed in the opening 278, thereby etching the features exposed in the opening 278. Operations of the second step may be in a same chamber as the first step.

In the embodiments represented in FIGS. 15A and 15B, the bias power is an DC power. By using a DC bias power, IAD may be improved, and efficiency of the plasma etching may be improved. In such embodiments, the plasma may be directed toward the structure 200 along directions 282′ as the arrows in FIG. 15B. An angle D3′ between the directions 282′ and a vertical direction (the dashed line) may be zero degree to about 7 degrees, alternatively zero degree to about 5 degrees. The level-to-level pulsing of the source power and the bias power disclosed herein improves IAD of the generated radicals and ions at the second step. Improved IAD may reduce variation of depths and/or widths of the first trench 262, reduce tapered angles (e.g., D1, D2) of the sidewalls of the first trench 262, and/or reduce variation of the tapered angles in different cross-sectional views (e.g., across the jog portion 262a in FIG. 8B and across the non-jog portion 262b in FIG. 8A). Thus, the angles D1 and D2 as in FIGS. 8A and 8B may be equal to or greater than zero and equal to or less than about 7 degrees. The relatively small D1 and D2 may increase available space for an L-shaped conducive feature to be formed in the first trench 262, and thus reduces resistance of the L-shaped conductive feature. In such embodiments, the difference between D1 and D2 may be less than about 1 degree.

In some embodiments, the third step includes a purging process. In the third step, an inert gas (e.g., nitrogen, helium) may be used to purge etching products (e.g., debris) from surfaces of the structure 200.

Various other etching parameters of the etching cycle can be tuned, such as etchant composition, etching temperature, etching solution concentration, etching pressure, Radio-Frequency (RF) bias voltage, etchant flow rate, other suitable etching parameters, or combinations thereof.

Referring back to FIGS. 1-2 and 13, the etching cycle may include a block 310 where a cleaning process is performed to the structure 200. The cleaning process may include a dry clean. Operations of block 310 may include purging a reactive gas and/or a carrier gas over the structure 200. The reactive gas and/or the carrier gas may include oxygen, nitrogen, methane, helium (He), hydrogen (H₂), or a combination thereof. In some embodiments, method 100 further includes operations at blocks 304 and 306 after block 302 and before the first etching cycle (including operations at blocks 304 and 306 in the first etching cycle).

Still referring to FIGS. 1-2 and 13, in some embodiments, the etching cycle may be repeated until a designed depth of the first trench 262 is reached. For example, upon completion of the first etching cycle, the first portion 262-1 of the first trench 262 is formed. The remaining dielectric liner 280′ may be etched down in the first etching cycle to have a negligible thickness. Then operations at blocks 304-310 are repeated to form a second portion (illustrated by dashed lines) of the first trench 262. At block 304, the dielectric liner 280 is formed on the sidewalls of the opening 278 and a bottom surface and sidewalls of the first portion 262-1. At block 306, the dielectric liner 280 is etched back to expose the gate structures 250 and the dielectric structure 238 and to form a remaining dielectric liner 280′ on sidewalls of the opening 278 and the first portion 262-1. The remaining dielectric liner 280′ may protect features (e.g., the hard mask layer 276, the dielectric structure 238) covered by the remaining dielectric liner 280′ in the following processes of the second etching cycle. At least a portion of the remaining dielectric liner 280′ may be etched down during the following processes of the second etching cycle. Upon completion of the second etching cycle, the second portion 262-2 of the first trench 262 is formed.

Similarly, each of the plurality of the etching cycles may vertically extend the first trench 262 as illustrated by the dashed lines. Upon completion of n etching cycles (n is an integer, e.g, 1, 2, 3, . . . ), a bottommost portion 262-n of the first trench 262 is formed, and the first trench 262 is completely formed. Because the thickness of the remaining dielectric liner 280′ is relatively small compared to the dimensions of the first trench 262, and because at least a portion of the remaining dielectric liner 280′ is etched down in the etching cycles, the remaining dielectric liner 280′ is omitted in the following figures and FIGS. 6 and 8A-9.

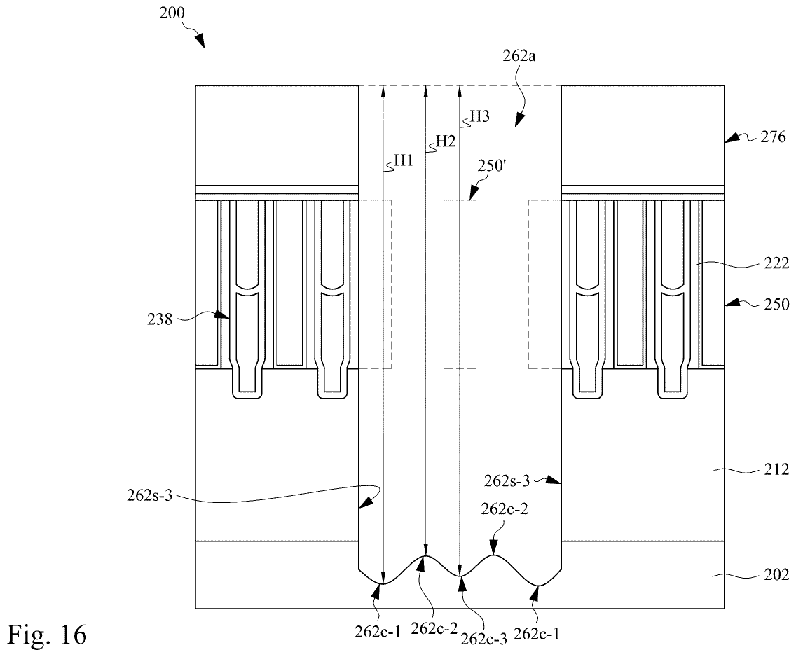

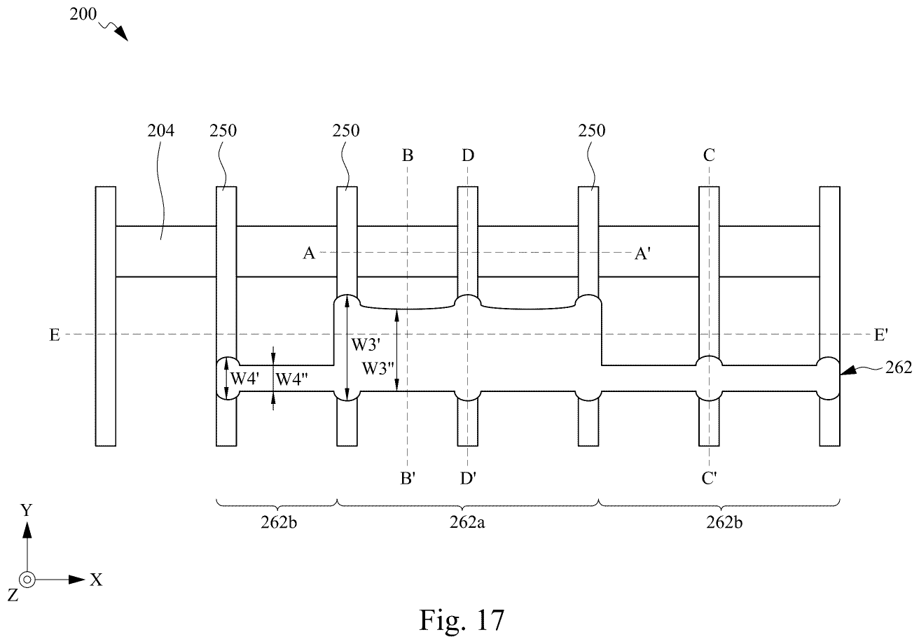

Referring to FIGS. 16-17, in some embodiments, the bottom surface and/or sidewalls of the first trench 262 may have wavy profiles in a cross-sectional view or a top view. FIG. 16 may illustrate a fragmentary cross-sectional view of the structure 200 taken along line E-E′ as in FIG. 17. In some embodiments, different materials of features (e.g., the gate structures 250, the dielectric structure 238, and the gate spacers 222) that are removed in forming the first trench 262 have different etching rate in the plurality of the etching cycles, thus depths of the first trench 262 is not uniform. In some embodiments, the gate structures 250 have a greater etching rate than dielectric materials (e.g., the dielectric structure 238 and the gate spacers 222). Thus, the first trench 262 has greater depths at positions vertically aligned to the dashed rectangles 250′. For example, a bottom surface of the first trench 262 has peaks 262c-2 and troughs 262c-1 and 262c-3 as depicted. The trough 262c-1, the peak 262c-2, and the trough 262c-3 may be positioned sequentially from closer to a sidewall 262s-3 of the first trench 262 to a middle of the bottom surface of the first trench 262. The depth corresponding to the peaks 262c-2 and troughs 262c-1 and 262c-3 from a level of a top surface of the hard mask layer 276 are H2, H1, and H3, respectively. H1 and H3 are greater than H2. In some embodiments, the etching rates to different features in forming middle portions of the first trench 262 are more balanced (e.g., having smaller differences) than that in forming side portions of the trench 262. In such embodiments, H1 is greater than H3. Depths variation in the middle portion of the first trench 262 may be less than depths variation in the side portions of the first trench 262. In some embodiments, variation of depths of the first trench 262 at different positions is about 10 nm to about 30 nm. In an example, a difference between H1 and H2 is between about 10 nm to about 30 nm.

Referring to FIG. 17, the different etching rates as described above may result in different widths of the first trench 262 in the top view. For example, the jog portion 262a of the first trench 262 may have a width W3′ at a position intersecting with the gate structure 250 and a width W3″ at a position between two neighboring gate structures 250. W3′ and W3″ are along the Y-direction, and W3′ is greater than W3″. Variation of widths of the jog portion 262a may be about 5 nm to about 35 nm, alternatively about 5 nm to about 20 nm. In an example, a difference between W3′ and W3″ is about 5 nm to about 35 nm. An average width of the jog portion 262a along the Y-direction is W3. W3 may be the same as W1 in FIG. 7.

For example, the non-jog portion 262b of the first trench 262 may have a width W4′ at a position intersecting with the gate structure 250 and a width W4″ at a position between two neighboring gate structure 250. W4′ and W4″ are along the Y-direction, and W4′ is greater than W4″. Variation of widths of the non-jog portion 262b may be about 5 nm to about 80 nm, alternatively about 5 nm to about 20 nm. In an example, a difference between W4′ and W4″ is about 5 nm to about 35 nm. An average width of the non-jog portion 262b along the Y-direction is W4. W4 may be the same as W2 in FIG. 7.

A gate isolation structure to be formed in the first trench 262 will track shapes and dimensions of the first trench 262, thus, depths and/or widths of the gate isolation structure may have the same variations as descried above. Depths and/or widths of the L-shaped conductive feature (to be described) to be formed inside the gate isolation structure may also have reduced variations. Therefore, control of a backside planarization process (e.g., a CMP process) to expose (or not to expose) the gate isolation structure and/or the L-shaped conductive feature may be improved.

The wavy profiles of the bottom surface and the sidewalls of the first trench 262 as in FIGS. 16-17 may be reflected in the profiles of the portions 262-1, 262-2, . . . , 262-n of the first trench 262 during the forming process of the first trench 262. For example, bottom surfaces of the portion portions 262-1, 262-2, . . . , 262-n may have similar wavy profiles. For illustration purpose, in the following figures, profiles of the bottom surfaces and the sidewalls of the first trench 262 and the features formed in the first trench 262, such as the gate isolation structure and the L-shaped conductive feature, are shown to have straight lines, but it is understood that the profiles may include wavy profiles as in FIGS. 16-17.

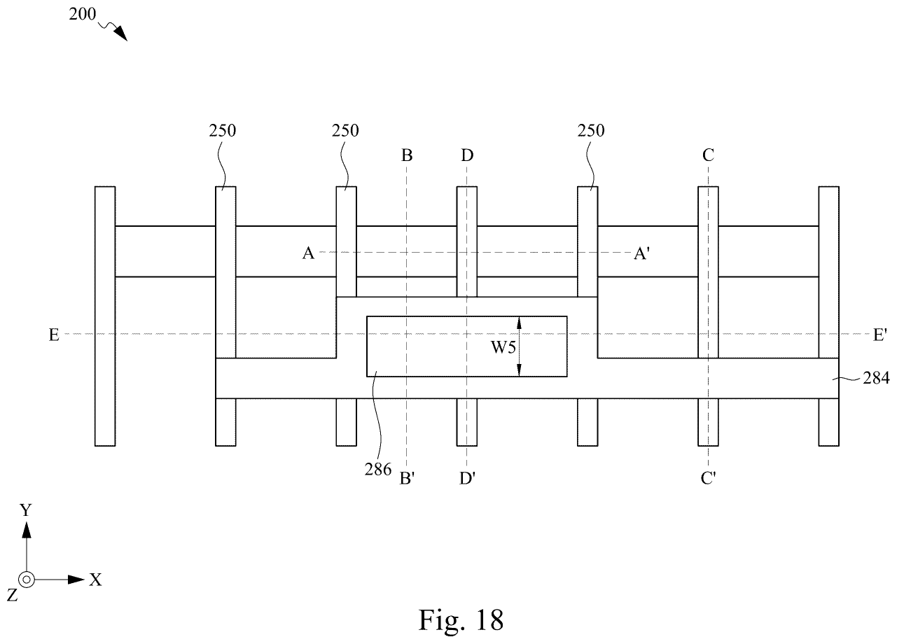

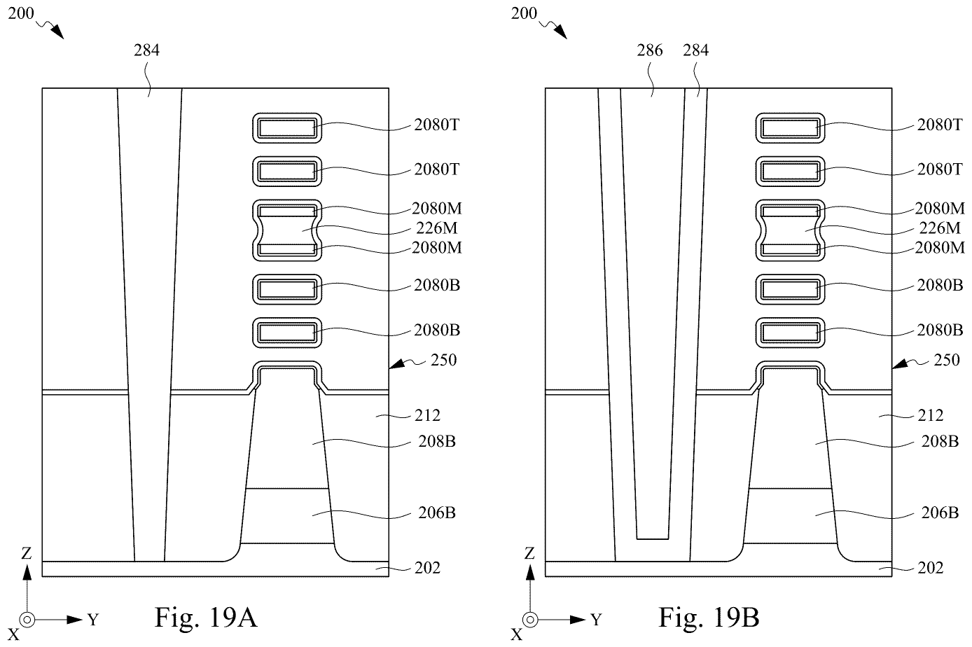

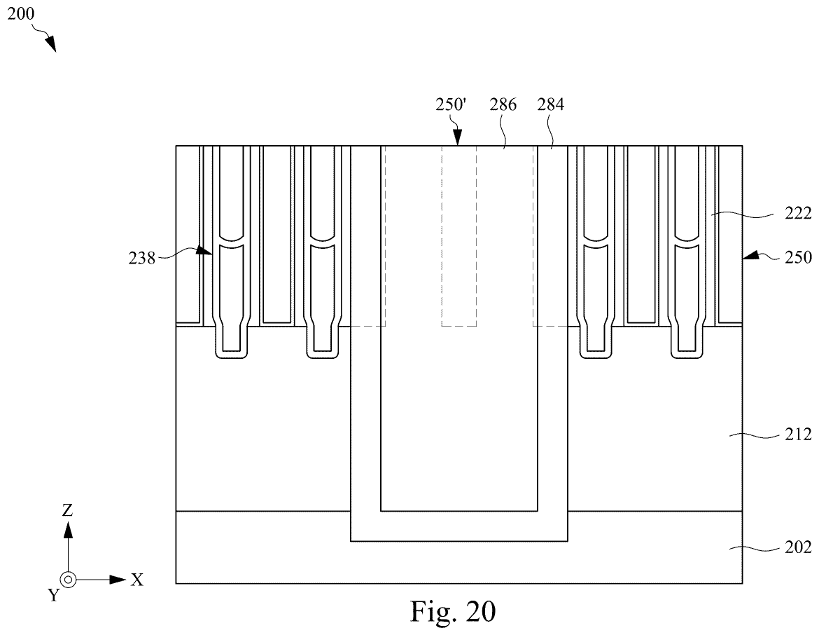

Referring to FIGS. 1 and 18-20, method 100 includes a block 106 where a dielectric layer 284 is deposited in the first trench 262. FIGS. 19A, 19B, and 20 illustrate fragmentary cross-sectional views of the structure 200 taken along lines C-C′, D-D′, E-E′, respectively, as in FIG. 18. The dielectric layer 284 separates the isolated segments of the gate structures 250 and may be referred to as a gate isolation structure 284. The dielectric layer 284 may be deposited by atomic layer deposition (ALD), chemical vapor deposition (CVD), Plasma-enhanced CVD (PECVD), flowable CVD, physical vapor deposition (PVD), other suitable methods, or combinations thereof. In some embodiments, the dielectric layer 284 is conformally deposited over the structure 200, including in the jog portion 262a and non-jog portions 262b of the first trench 262. The dielectric layer 284 may be deposited along the sidewalls and the bottom surface of the first trench 262. In the depicted embodiment, the thickness of the dielectric layer 284 is controlled, such that the dielectric layer 284 on the sidewalls and the bottom surface of the non-jog portion 262b merges. In other words, the dielectric layer 284 fills the entirety of the non-jog portions 262b. Because the jog portion 262a is wider than the non-jog portions 262b along the Y-direction, the dielectric layer 284 partially fills the jog portion 262a. The dielectric layer 284 along the sidewalls of the jog portion 262a may not merge, leaving a middle portion (i.e., where a conductive layer 286 is to be filled) of the jog portion 262a unfilled. The middle portion may have an averaged width W5 of about 10 nm to about 50 nm. The variation of widths of the jog portion 262a and the variation of widths of the non-jog portion 262b as described above may allow forming of the dielectric layer 284 as described herein. The dielectric layer 284 may be in direct contact with the gate structure 250, the isolation feature 212, the substrate 202, the dielectric structure 238, and the gate spacers 222. In some implementations, the dielectric layer 284 includes silicon nitride.

Still referring to FIGS. 1 and 18-20, method 100 includes a block 108 where a conductive layer 286 is filled in the middle portion of the jog portion 262a and over the dielectric layer 284. The conductive layer 286 is spaced apart from the gate structures 250, the dielectric structure 238, the isolation feature 212, and the substrate 202 by the dielectric layer 284. The conductive layer 286 may include any suitable material, such as W, Co, Ru, Cu, Ta, Ti, Al, Mo, other suitable conductive materials, or combinations thereof. The conductive layer 286 may be deposited by any suitable method, such as CVD, PVD, ALD, plating, other suitable methods, or combinations thereof. Thereafter, a planarization process (e.g. a CMP process) may be performed to the structure 200 to remove excess materials of the dielectric layer 284 and the conductive layer 286. Top surfaces of the dielectric layer 284, the conductive layer 286, the gate structures 250, and the dielectric structure 238 may be coplanar.

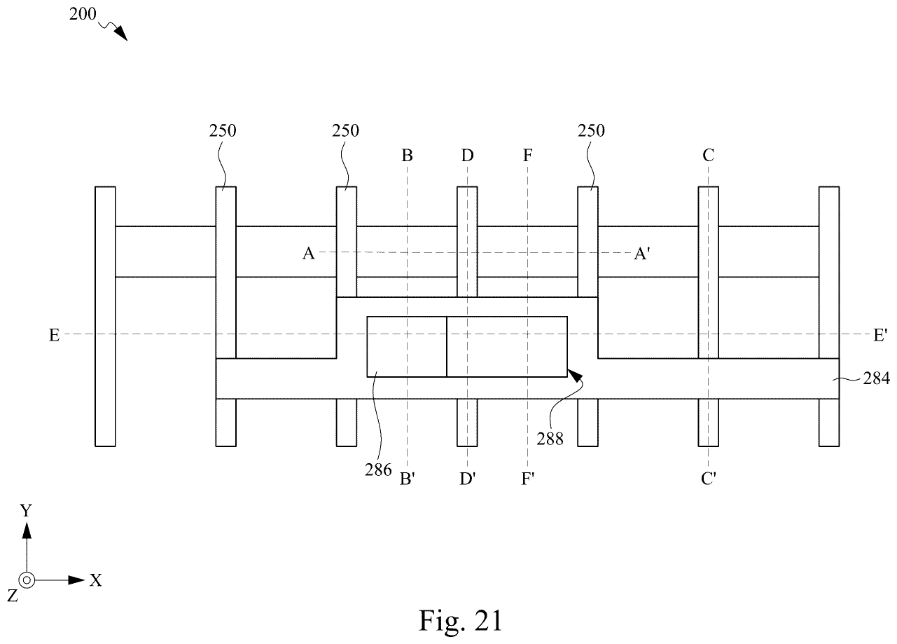

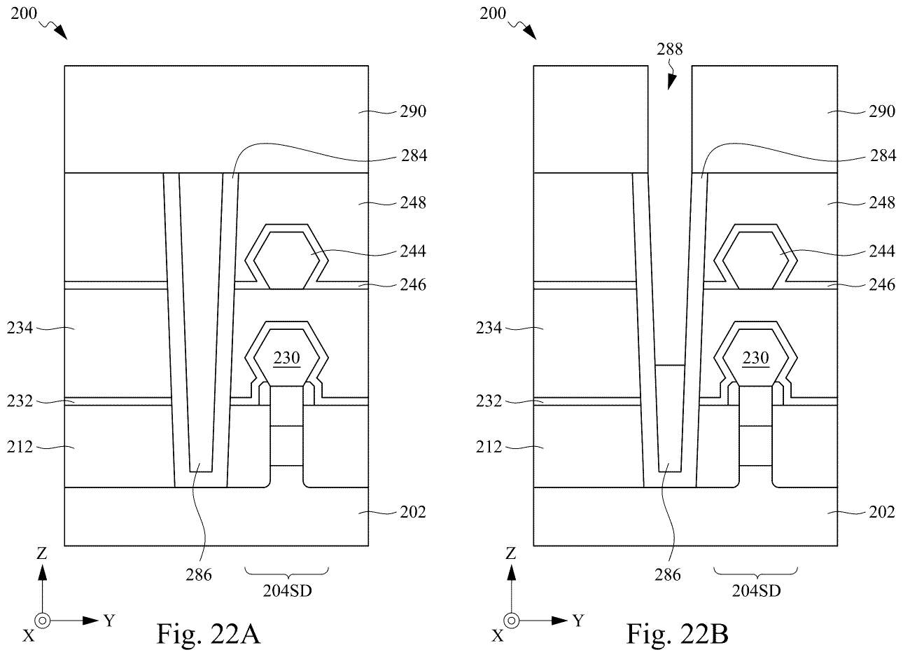

Referring to FIGS. 1 and 21-24, method 100 includes a block 110 where the conductive layer 286 is etched back to form a second trench 288. FIGS. 22A, 22B, 23, and 24 illustrate fragmentary cross-sectional views of the structure 200 taken along lines B-B′, F-F′, D-D′, E-E′, respectively, as in FIG. 21. In an example process, a hard mask layer and a photoresist are deposited over the workpiece 200. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer to form the patterned hard mask layer 290. The patterned hard mask layer 290 is then applied as an etch mask to etch the conductive layer 286. The patterned hard mask layer 290 may have an opening exposing a portion of the conductive layer 286. The etch process may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, oxygen, hydrogen, other suitable gases, or combinations thereof. The time duration of the etch process may be controlled to achieve a designed depth of the second trench 288.

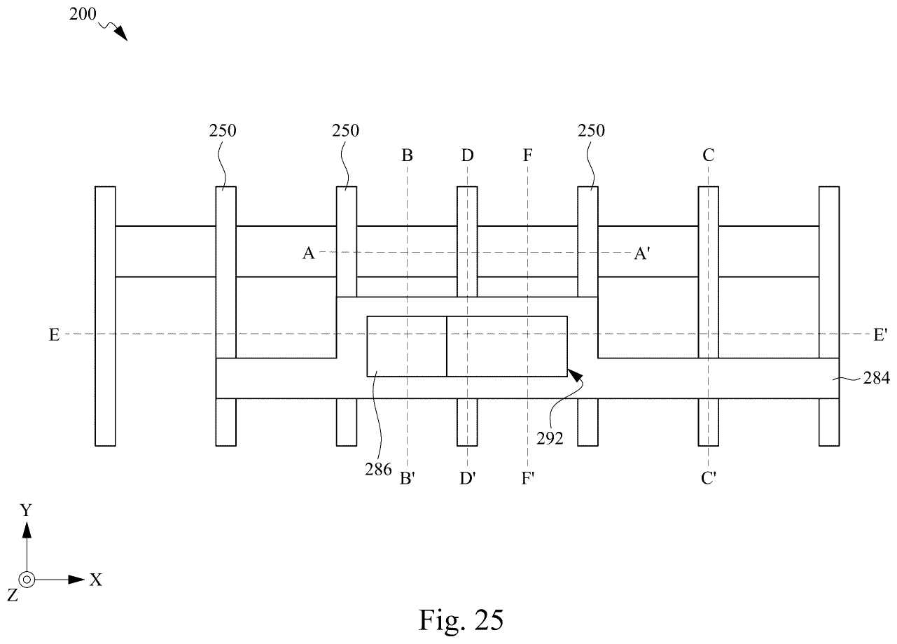

Referring to FIG. 21, the second trench 288 may have a same width along the Y-direction as the conductive layer 286. In the top view, the second trench 288 extends from one side (e.g., left side) of one of the gate structures 250 to the dielectric layer 284 along the X-direction. Referring to FIG. 22B, a bottom surface of the second trench 288 may be at a same level or above a bottom surface of the source/drain feature 230. In some embodiments, the bottom surface of the second trench 288 is above a top surface of the isolation feature 212. Referring to FIG. 25, after forming the second trench 288, the conductive layer 286 has an L-shape in the cross-sectional view and may be referred to as an L-shaped conductive feature 286. The L-shaped conductive feature 286 may be connected to a top source/drain contact and a bottom source/drain contact (to be described below). The dotted rectangles 286-1 and 286-2 illustrate available projected positions (e.g., in the cross-sectional view of FIG. 25) for the connections with the top source/drain contact and the bottom source/drain contact, respectively. The dotted rectangles 286-1 and 286-2 are in a vertical portion and a horizontal portion of the L-shaped conductive feature 286, respectively.

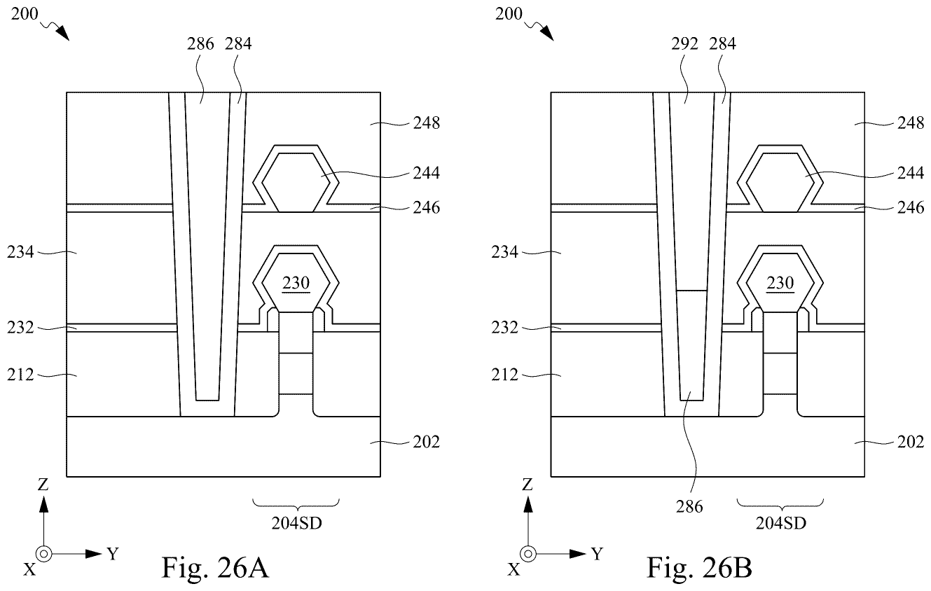

Referring to FIGS. 1 and 25-28, method 100 includes a block 112 where an insulation structure 292 is filled in the second trench 288. FIGS. 26A, 26B, 27, and 28 illustrate fragmentary cross-sectional views of the structure 200 taken along lines B-B′, F-F′, D-D′, E-E′, respectively, as in FIG. 25. The insulation structure 292 includes silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). In the depicted embodiments, the insulation structure 292 includes silicon oxide. Insulation structure 292 may be a single layer structure or a multilayer structure. In some embodiments, the insulation structure 292 is formed by depositing at least one dielectric material/layer over the structure 200 (including in the second trench 288) and performing a planarization process (e.g., a CMP process). The insulation structure 292 may be deposited using spin-on coating, ALD, CVD, FCVD, or a suitable method. The insulation structure 292 traces shape and dimensions of the second trench 288.

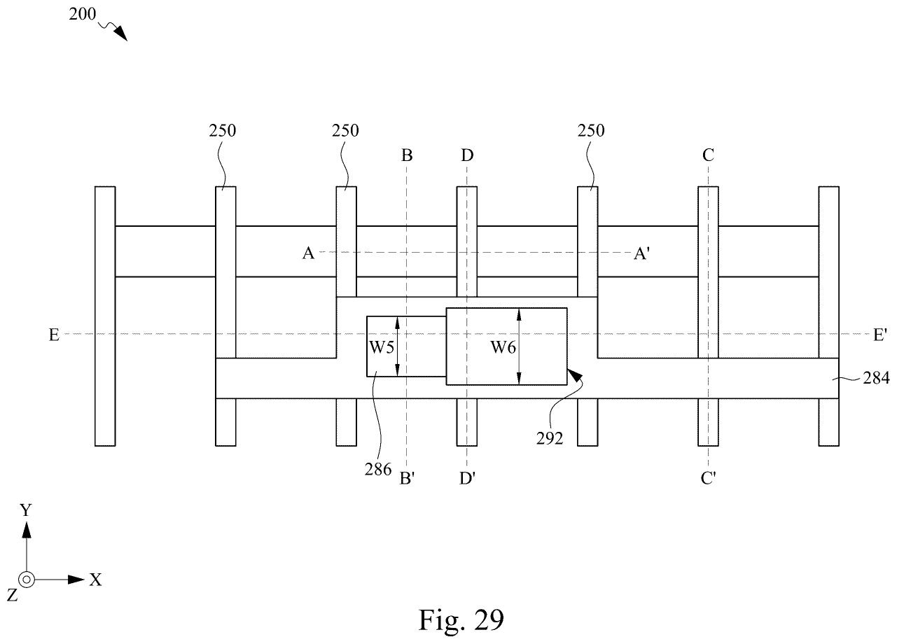

Referring to FIG. 29, in some embodiments, forming the second trench 288 further removes a portion of the dielectric layer 284. In such embodiments, the insulation structure 292 has a width W6 along the Y-direction. W6 may be about 12 nm to about 55 nm and may be greater than W5.

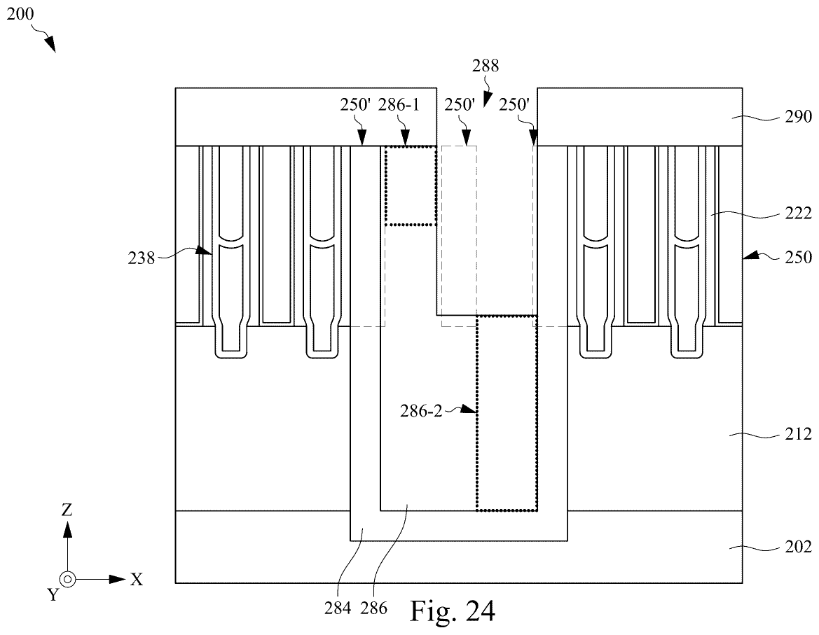

Referring to FIGS. 1 and 30-31, method 100 includes a block 114 where source/drain contacts are formed to connect to the source/drain features 244 and 230, respectively. Some of the source/drain contacts may be connected by the L-shaped conductive feature 286. For clarity, the source/drain features 244 on the left side and right side are labeled as 244-1 and 244-2, respectively; the source/drain features 230 on the left side and right side are labeled as 230-1 and 230-2, respectively. The source/drain contacts may include top source/drain contacts 294-1 and 294-2 and a bottom source/drain contact 296. The top source/drain contact 294-1 may be connected to the vertical portion of the L-shaped conductive feature 286, and the bottom source/drain contact 296 may be connected to the horizontal portion of the L-shaped conductive feature 286. Projection of the top source/drain contact 294-1 in the cross-sectional view in FIG. 24 may be within the dotted rectangle 286-1, projection of the bottom source/drain contact 296 in the cross-sectional view in FIG. 24 may be within the dotted rectangle 286-2. Thus, the top source/drain contact 294-1 and the bottom source/drain contact 296 are connected by the L-shaped conductive feature 286. Thus, the conductive layer 286 may also be referred to as a vertical local interconnection 286.

Forming the top source/drain contacts 294-1 and 294-2 and the bottom source/drain contact 296 may include forming source/drain contact openings in the dielectric structure 238 and the bottom silicon layer 208B, the bottom silicon germanium layer 206B, and the substrate 202 (e.g., shown in FIG. 4), depositing a conductive material in the source/drain contact openings, and performing a planarization process to remove excess conductive materials. The top source/drain contact 294-1 and 294-2 and the bottom source/drain contact 296 may be formed separately. The conductive material may include any suitable material, such as W, Co, Ru, Cu, Ta, Ti, Al, Mo, other suitable conductive materials, or combinations thereof. The conductive material may be deposited by any suitable method, such as CVD, PVD, ALD, plating, other suitable methods, or combinations thereof.

Before forming the source/drain contacts, a silicide layer (not depicted) may be formed over the source/drain features 244 and/or below the source/drain features 230. In some embodiments, the silicide layer includes a metal silicide, such as nickel silicide, cobalt silicide, tungsten silicide, tantalum silicide, titanium silicide, platinum silicide, erbium silicide, palladium silicide, other suitable silicides, or combinations thereof. The silicide layer may be formed by a deposition process such as CVD, ALD, PVD, other suitable processes, or combinations thereof. For example, a metal layer (e.g., nickel) may be deposited over the source/drain features 244 and/or under the source/drain features 230. Then, the structure 200 is annealed to allow the metal layer and the semiconductor materials of the source/drain features 244 and/or 230 to react. Thereafter, the un-reacted metal layer is removed, leaving the silicide layer over the source/drain features 244 and/or under the source/drain features 230. Alternatively, the silicide layer may be directly formed over the source/drain features 244 and/or under the source/drain features 230 by any suitable deposition method, such as CVD, ALD, PVD, other suitable methods, or combinations thereof. The silicide layer over the source/drain features 244 or under the source/drain features 230 may be formed separately.

The structure 200 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over and below the substrate 202, configured to connect the various features to form a functional circuit that may include one or more devices including the structure 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. In the further processing, backside planarization processes (e.g., a CMP process) may be performed to the structure (e.g., including the gate isolation structure 284. The reduced variation of the depths of the first trench 262 may result in improved control of the backside planarization processes.

One of ordinary skill may recognize although FIGS. 3-31 illustrate stacked transistor structures having GAA transistors, other examples of semiconductor devices (e.g., multigate devices, stacked transistor structures having other multigate devices) may benefit from aspects of the present disclosure.

Although not intended to be limiting, one or more embodiments of the present disclosure provide many benefits to a semiconductor device. For example, the present disclosure reduces variation of depths and/or widths of the gate isolation structure by performing a plurality of etching cycles in forming the gate isolation trench. Thus, control of backside processes (e.g., a CMP process) to the structure may be improved. Thus, yield of the semiconductor structures may be improved.

In one exemplary aspect, the present disclosure is directed to a method. The method includes providing a structure. The structure includes a substrate, a stack of channel layers disposed over the substrate, a metal gate structure disposed over and wrapping around the stack of channel layers and extending lengthwise along a first direction from a top view, and source/drain features disposed on two sides of the metal gate structure and connected to the stack of channel layers. The method further includes forming a trench vertically extending through the metal gate structure and from the top view extending lengthwise along a second direction perpendicular to the first direction, and forming a gate isolation feature and a conductive feature in the trench. The conductive feature is surrounded by the gate isolation feature from the top view. Forming the trench includes a plurality of plasma etching cycles, each plasma etching cycle including a first step and a second step. The first step has a first source power and a first bias power, and the second step has a second source power and a second bias power. The first source power is different from the second source power and the first bias power is less than the second bias power.

In some embodiments, the trench includes a first portion having a first width and a second portion having a second width smaller than the first width, the first portion and the second portion are connected, and the first width and the second width are along the first direction. In some embodiments, the first portion of the trench has a first depth, a second depth, and a third depth from adjacent to the second portion to a middle of the first portion, the first depth is greater than the third depth, and the third depth is greater than the second depth. In some embodiments, before forming the trench, the method further includes forming a patterned hard mask over the structure and having an opening exposing the metal gate structure. Before the first step, the each plasma etching cycle further includes forming an oxide layer along sidewalls of the opening, and performing a dry etching process to the oxide layer, thereby exposing the metal gate structure. In some embodiments, a sidewall of the trench has a wavy profile from the top view, a maximum difference between a peak and a trough of the wavy profile is about 5 nm to about 80 nm. In some embodiments, forming the gate isolation feature and the conductive feature in the trench includes depositing a first dielectric layer along a bottom surface and sidewalls of the trench, leaving a center portion of the trench unfilled, depositing a metal layer in the center portion of the trench and over the first dielectric layer, and replacing a top portion of the metal layer with a second dielectric layer, thereby forming the conductive feature, the conductive feature has an L-shape in a cross-sectional view. In some embodiments, the first step has a first time duration and the second step has a second time duration less than the first time duration. In some embodiments, the stack of channel layers is a first stack of channel layers, the source/drain features are first source/drain features, and the structure further includes a second stack of channel layers disposed over the substrate and above the first stack of channel layers, and second source/drain features disposed on two sides of the metal gate structure and connected to the second stack of channel layers, the metal gate structure is disposed over and wrapping around the second stack of channel layers, the first stack of channel layers and the second stack of channel layers are separated by a dielectric layer. In some embodiments, the method further includes forming a first source/drain contact connected to one of the first source/drain features, and forming a second source/drain contact connected to one of the second source/drain features, the conductive feature is connected to the first source/drain contact and the second source/drain contact. In some embodiments, the each plasma etching cycle further includes a third step after the second step, the third step has a third source power of zero and a third bias power of zero, and the third step includes purging a carrier gas to clean surfaces of the structure. In some embodiments, the first bias power and the second bias power are AC bias power or DC bias power.

In another exemplary aspect, the present disclosure is directed to a method. The method includes forming a metal gate structure wrapping around a stack of channel layers, forming a trench cutting the metal gate structure into two isolated segments, and forming a gate isolation structure in the trench. Forming the trench includes performing a plasma etching process to the metal gate structure, the plasma etching process includes a first step and a second step after the first step, the first step has a first source power and a first bias power, the second step has a second source power and a second bias power, a ratio of the first source power to the second source power is about 1:1 to about 5:1, and the first bias power is less than the second bias power.

In some embodiments, depths of the trench have a variation of about 10 nm to about 30 nm. In some embodiments, before performing the plasma etching process, forming the trench further includes forming a patterned hard mask over the metal gate structure, the patterned hard mask having an opening exposing the metal gate structure, conformally depositing an oxide layer in the opening, and performing an etching process to the oxide layer, thereby exposing the metal gate structure. In some embodiments, the trench includes a jog portion intersecting with the metal gate structure and a non-jog portion connected to the jog portion, the jog portion has a first width and the non-jog portion has a second width less than the first width, the two isolated segments are arranged along a direction from a top view, the first width and the second width are along the direction from the top view. In some embodiments, forming the gate isolation structure in the trench includes depositing a first dielectric layer on sidewalls and a bottom surface of the non-jog portion and the jog portion of the trench, depositing a conductive layer over a second portion of the first dielectric layer in the jog portion of the trench, removing a top portion of the conductive layer to form an opening, thereby forming an L-shaped conductive feature from the conductive layer, and depositing a second dielectric layer in the opening. A first portion of the first dielectric layer on sidewalls of the non-jog portion laterally merges.

In yet another exemplary aspect, the present disclosure is directed to a method. The method includes receiving a structure. The structure includes a substrate, a first stack of channel layers disposed over the substrate, a second stack of channel layers disposed over the first stack of channel layers, a middle dielectric layer disposed between the first stack of channel layers and the second stack of channel layers, and a gate structure disposed over and wrapping around the first stack of channel layers and the second stack of channel layers. The method further includes forming a trench to cut the gate structure into two isolated segments, and forming a gate isolation feature and an L-shaped conductive feature in the trench. Forming the trench includes performing a plurality of plasma etching processes having a source power and a DC bias power. At least one of the plurality of plasma etching processes includes a plasma generating step, an etching step, and a cleaning step. The source power has a first step increase from the plasma generating step to the etching step. The DC bias power has a second step increase from the plasma generating step to the etching step.

In some embodiments, the cleaning step includes purging an inert gas over the structure, and the source power and the DC bias power are zero in the cleaning step. In some embodiments, plasma generated in the plasma generating step is directed toward the structure in a direction in the etching step, an angle between the direction and a vertical direction is less than about 7 degrees. In some embodiments, the DC bias power is zero in the plasma generating step.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a structure including:
a substrate,
a stack of channel layers disposed over the substrate,
a metal gate structure disposed over and wrapping around the stack of channel layers and extending lengthwise along a first direction from a top view, and
source/drain features disposed on two sides of the metal gate structure and connected to the stack of channel layers;
forming a trench vertically extending through the metal gate structure and from the top view extending lengthwise along a second direction perpendicular to the first direction; and
forming a gate isolation feature and a conductive feature in the trench,
wherein the conductive feature is surrounded by the gate isolation feature from the top view,
wherein forming the trench includes a plurality of plasma etching cycles, each plasma etching cycle including a first step and a second step,
wherein the first step has a first source power and a first bias power, and the second step has a second source power and a second bias power,
wherein the first source power is different from the second source power and the first bias power is less than the second bias power.

2. The method of claim 1, wherein the trench includes a first portion having a first width and a second portion having a second width smaller than the first width,
wherein the first portion and the second portion are connected, and
wherein the first width and the second width are along the first direction.

3. The method of claim 2, wherein the first portion of the trench has a first depth, a second depth, and a third depth from adjacent to the second portion to a middle of the first portion,
wherein the first depth is greater than the third depth, and the third depth is greater than the second depth.

4. The method of claim 1, before forming the trench, further comprising forming a patterned hard mask over the structure and having an opening exposing the metal gate structure; and
wherein before the first step, the each plasma etching cycle further includes:
forming an oxide layer along sidewalls of the opening, and
performing a dry etching process to the oxide layer, thereby exposing the metal gate structure.

5. The method of claim 1, wherein a sidewall of the trench has a wavy profile from the top view,
wherein a maximum difference between a peak and a trough of the wavy profile is about 5 nm to about 80 nm.

6. The method of claim 1, wherein forming the gate isolation feature and the conductive feature in the trench includes:
depositing a first dielectric layer along a bottom surface and sidewalls of the trench, leaving a center portion of the trench unfilled,
depositing a metal layer in the center portion of the trench and over the first dielectric layer,
replacing a top portion of the metal layer with a second dielectric layer, thereby forming the conductive feature,
wherein the conductive feature has an L-shape in a cross-sectional view.

7. The method of claim 1, wherein the first step has a first time duration and the second step has a second time duration less than the first time duration.

8. The method of claim 1, wherein the stack of channel layers is a first stack of channel layers, the source/drain features are first source/drain features, and
wherein the structure further includes:
a second stack of channel layers disposed over the substrate and above the first stack of channel layers, and
second source/drain features disposed on two sides of the metal gate structure and connected to the second stack of channel layers,
wherein the metal gate structure is disposed over and wrapping around the second stack of channel layers,
wherein the first stack of channel layers and the second stack of channel layers are separated by a dielectric layer.

9. The method of claim 8, further comprising:
forming a first source/drain contact connected to one of the first source/drain features; and
forming a second source/drain contact connected to one of the second source/drain features,
wherein the conductive feature is connected to the first source/drain contact and the second source/drain contact.

10. The method of claim 1, wherein the each plasma etching cycle further includes a third step after the second step,
wherein the third step has a third source power of zero and a third bias power of zero, and
wherein the third step includes purging a carrier gas to clean surfaces of the structure.

11. The method of claim 1, wherein the first bias power and the second bias power are AC bias power or DC bias power.

12. A method, comprising:
forming a metal gate structure wrapping around a stack of channel layers;
forming a trench cutting the metal gate structure into two isolated segments; and
forming a gate isolation structure in the trench,
wherein forming the trench includes performing a plasma etching process to the metal gate structure, the plasma etching process includes a first step and a second step after the first step,
wherein the first step has a first source power and a first bias power, the second step has a second source power and a second bias power,
wherein a ratio of the first source power to the second source power is about 1:1 to about 5:1, and
wherein the first bias power is less than the second bias power.

13. The method of claim 12, wherein depths of the trench have a variation of about 10 nm to about 30 nm.

14. The method of claim 12, wherein before performing the plasma etching process, forming the trench further includes:
forming a patterned hard mask over the metal gate structure, the patterned hard mask having an opening exposing the metal gate structure,
conformally depositing an oxide layer in the opening, and
performing an etching process to the oxide layer, thereby exposing the metal gate structure.

15. The method of claim 12, wherein the trench includes a jog portion intersecting with the metal gate structure and a non-jog portion connected to the jog portion,
wherein the jog portion has a first width and the non-jog portion has a second width less than the first width,
wherein the two isolated segments are arranged along a direction from a top view,
wherein the first width and the second width are along the direction from the top view.

16. The method of claim 15, wherein forming the gate isolation structure in the trench includes:
depositing a first dielectric layer on sidewalls and a bottom surface of the non-jog portion and the jog portion of the trench, wherein a first portion of the first dielectric layer on sidewalls of the non-jog portion laterally merges,
depositing a conductive layer over a second portion of the first dielectric layer in the jog portion of the trench,
removing a top portion of the conductive layer to form an opening, thereby forming an L-shaped conductive feature from the conductive layer, and
depositing a second dielectric layer in the opening.

17. A method, comprising:
receiving a structure including:
a substrate,
a first stack of channel layers disposed over the substrate,
a second stack of channel layers disposed over the first stack of channel layers,
a middle dielectric layer disposed between the first stack of channel layers and the second stack of channel layers, and
a gate structure disposed over and wrapping around the first stack of channel layers and the second stack of channel layers;
forming a trench to cut the gate structure into two isolated segments; and
forming a gate isolation feature and an L-shaped conductive feature in the trench,
wherein forming the trench includes performing a plurality of plasma etching processes having a source power and a DC bias power,
wherein at least one of the plurality of plasma etching processes includes a plasma generating step, an etching step, and a cleaning step,
wherein the source power has a first step increase from the plasma generating step to the etching step,
wherein the DC bias power has a second step increase from the plasma generating step to the etching step.

18. The method of claim 17, wherein the cleaning step includes purging an inert gas over the structure, and
wherein the source power and the DC bias power are zero in the cleaning step.

19. The method of claim 17, wherein plasma generated in the plasma generating step is directed toward the structure in a direction in the etching step,
wherein an angle between the direction and a vertical direction is less than about 7 degrees.

20. The method of claim 17, wherein the DC bias power is zero in the plasma generating step.
